(19) United States
(12) Patent Application Publication
(10) Pub. No.: US 2026/0126509 A1
(43) Pub. Date: May 7, 2026

(54) MAGNETIC RESONANCE IMAGING APPARATUS, GRADIENT MAGNETIC POWER SUPPLY APPARATUS, AND ABNORMALITY DETECTION METHOD

(71) Applicant: CANON MEDICAL SYSTEMS CORPORATION, Otawara-shi (JP)

(72) Inventors: Yoshinobu SHINOZAKI, Otawara (JP); Makoto TAKANAKA, Nasushiobara (JP); Koichi YAMAKAWA, Nasushiobara (JP); Masao ITO, Nasushiobara (JP)

(73) Assignee: CANON MEDICAL SYSTEMS CORPORATION, Otawara-shi (JP)

(21) Appl. No.: 19/373,928

(22) Filed: Oct. 30, 2025

(30) Foreign Application Priority Data
Nov. 1, 2024 (JP) 2024-193082

(51) Int. Cl. G01R 33/58; G01R 33/36

(52) U.S. Cl. CPC G01R 33/583; G01R 33/36

(57) ABSTRACT

A magnetic resonance imaging apparatus includes a gradient coil, a gradient magnetic field power supply, and processing circuitry. The gradient coil generates a gradient magnetic field. The gradient magnetic field power supply includes a power supply device configured to supply power, a capacitor configured to accumulate power supplied from the power supply device, and an amplifier configured to operate based on power supplied from at least one of the power supply device and the capacitor and amplify an input signal, and outputs the amplified signal to the gradient coil. The processing circuitry is configured to detect a voltage across the capacitor, determine a value corresponding to an impedance of the gradient coil, measure a period required for the voltage across the capacitor to decrease from a first predetermined value to a second predetermined value by self-discharge based on the detected voltage, and detect an abnormality in at least one of the capacitor and the gradient coil based on the determined value corresponding to the impedance and the measured period.

### CROSS-REFERENCE TO RELATED APPLICATIONS

This application is based upon and claims the benefit of priority from Japanese Patent Application No. 2024-193082, filed Nov. 1, 2024, the entire contents of which are incorporated herein by reference.

### FIELD

Embodiments of this application relate to a magnetic resonance imaging apparatus, a gradient magnetic power supply apparatus, and an abnormality detection method.

### BACKGROUND

In a magnetic resonance imaging apparatus of related art, a gradient coil cannot fulfill its original function due to an increase in the impedance of the gradient coil. In this regard, for example, Japanese Patent Laid-Open No. 2017-108968 describes a technique in which performance degradation (abnormality) of a gradient coil is detected based on the impedance of the gradient coil.

However, a change in the impedance of a gradient coil may be caused due to an abnormality in a capacitor provided in a gradient magnetic field power supply even in a case where no abnormality is detected in the gradient coil. In other words, in the configuration of related art, it has been difficult to determine whether an abnormality has occurred in the gradient coil, or whether an abnormality has occurred in the capacitor. Therefore, there is a demand for providing a configuration for identifying an abnormality section.

### BRIEF DESCRIPTION OF THE DRAWINGS

FIG. 1 is a block diagram illustrating a configuration example of a magnetic resonance imaging apparatus according to one embodiment;

FIG. 2 is a block diagram illustrating a schematic configuration example of a gradient magnetic field power supply and the like according to the embodiment;

FIG. 3 illustrates a schematic circuitry configuration example relating to a gradient coil according to the embodiment;

FIG. 4 illustrates a circuitry configuration example in the gradient magnetic field power supply according to the embodiment;

FIG. 5 illustrates an example of a connection relation between a capacitor bank and a measurement device according to the embodiment;

FIG. 6 is a graph illustrating an example of each of a voltage V_{c}, a supplied current Iₚ, and an output current I of the capacitor bank during a current supply period according to the embodiment;

FIG. 7 is a graph illustrating an example of frequency dependencies of a voltage V_{c}(t) (R is constant) and a drop voltage V_{c}(t) of the capacitor bank when the resistance of the gradient coil is constant (frequency-independent) according to the embodiment;

FIG. 8 is a graph illustrating a relationship between the drop voltage V_{c}(t) of the capacitor bank with respect to a frequency ω of an output current I(t) and a resistance R(ω) of the gradient coil according to the embodiment;

FIG. 9 is a graph illustrating frequency dependencies of a resistance-frequency curve R(ω) and an inductance L(ω) in the gradient coil according to the embodiment;

FIG. 10 is a graph illustrating an example of a discharge characteristic of the capacitor bank at the time of installation according to the embodiment;

FIG. 11 is a graph illustrating an example of the discharge characteristic of the capacitor bank at the time of degradation according to the embodiment;

FIG. 12 illustrates an example of a graph relating to the detection of an abnormality in at least one of the gradient coil and the capacitor bank according to the embodiment;

FIG. 13 is a flowchart illustrating an example of processing to be performed by the magnetic resonance imaging apparatus according to the embodiment; and

FIG. 14 is a flowchart illustrating an example of processing to be performed by the magnetic resonance imaging apparatus according to the embodiment.

### DETAILED DESCRIPTION

A magnetic resonance imaging apparatus according to an embodiment of the present disclosure includes a gradient coil, a gradient magnetic field power supply, and processing circuitry. The gradient coil generates a gradient magnetic field. The gradient magnetic field power supply includes a power supply device configured to supply power, a capacitor configured to accumulate power supplied from the power supply device, and an amplifier configured to operate based on power supplied from at least one of the power supply device and the capacitor and amplify an input signal, and outputs the amplified signal to the gradient coil. The processing circuitry is configured to detect a voltage across the capacitor, determine a value corresponding to an impedance of the gradient coil, measure a period required for the voltage across the capacitor to decrease from a first predetermined value to a second predetermined value by self-discharge based on the detected voltage, and detect an abnormality in at least one of the capacitor and the gradient coil based on the determined value corresponding to the impedance and the measured period.

Various Embodiments will be described hereinafter with reference to the accompanying drawings.

A magnetic resonance imaging apparatus, a gradient magnetic power supply apparatus, and an abnormality detection method according to embodiments will be described in detail below with reference to the attached drawings. In the following description, components having substantially the same functions and configurations are denoted by the same reference numerals and repeated description is given only where necessary.

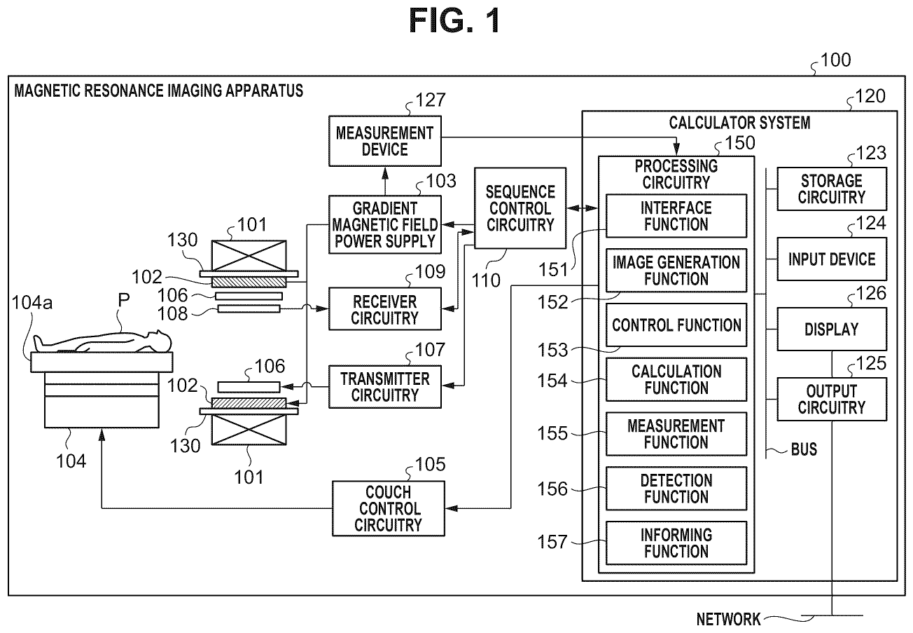

An overall configuration of a magnetic resonance imaging apparatus 100 according to an embodiment of the present disclosure will now be described with reference to FIG. 1. FIG. 1 is a block diagram illustrating a configuration example of the magnetic resonance imaging apparatus 100 according to the present embodiment.

As illustrated in FIG. 1, the magnetic resonance imaging apparatus 100 includes a static magnetic field magnet 101, a shim coil 130, a gradient coil 102, a gradient magnetic field power supply 103, a couch 104, a couch control circuitry 105, a transmission coil 106, a transmitter circuitry 107, a reception coil 108, a receiver circuitry 109, a sequence control circuitry 110, a calculator system 120, and a measurement device 127. The magnetic resonance imaging apparatus 100 does not include a subject P (e.g., a human body).

The static magnetic field magnet 101 is a magnet formed in a hollow cylindrical shape, and generates a uniform magnetostatic field in an internal space. The static magnetic field magnet 101 is, for example, a permanent magnet, a superconducting magnet, or a resistive magnet.

The shim coil 130 is a coil formed in a hollow cylindrical shape on the inside of the static magnetic field magnet 101, and is connected to a shim coil power supply (not illustrated), and makes the magnetostatic field generated by the static magnetic field magnet 101 uniform by power supplied from the shim coil power supply.

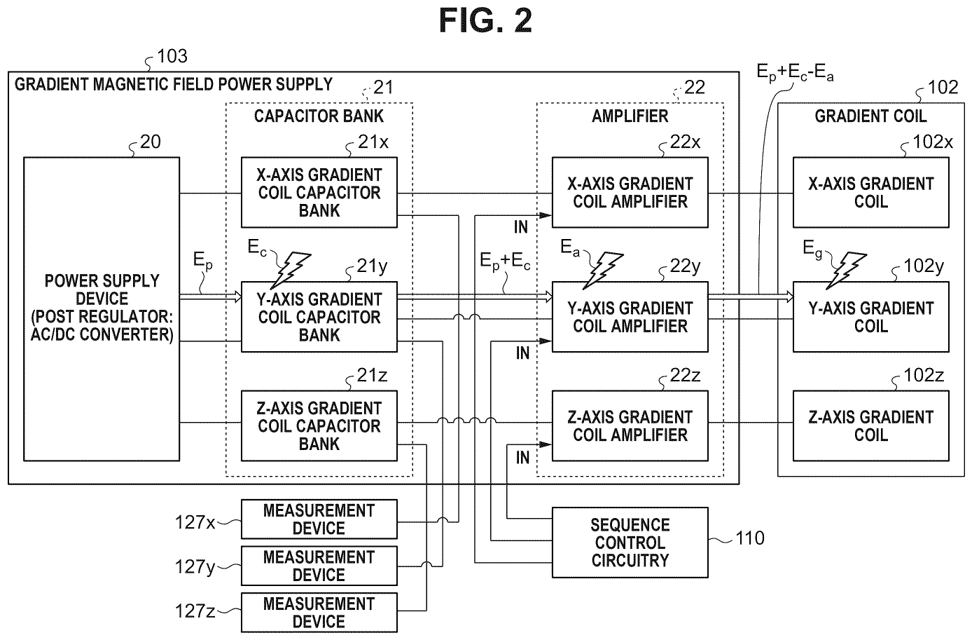

The gradient coil 102 is a coil formed in a hollow cylindrical shape, and is located on the inside of the static magnetic field magnet 101 and the shim coil 130. As illustrated in FIG. 2, the gradient coil 102 is formed by combining three coils (an X-axis gradient coil 102x, a Y-axis gradient coil 102y, and a Z-axis gradient coil 102z) respectively corresponding to an X-axis, a Y-axis, and a Z-axis that are orthogonal to each other.

The three coils individually receive currents from the gradient magnetic field power supply 103, and generate gradient magnetic fields with varying magnetic field intensities along the X-axis, the Y-axis, and the Z-axis, respectively. The Z-axis direction is coincident with a static magnetic field direction. The Y-axis direction corresponds to the vertical direction, and the X-axis direction is perpendicular to each of the Z-axis and the Y-axis.

The gradient magnetic fields of the X-axis, the Y-axis, and the Z-axis generated by the gradient coil 102 form, for example, a slice selection gradient magnetic field Gs, a phase encoding gradient magnetic field Ge, and a read-out gradient magnetic field Gr.

The slice selection gradient magnetic field Gs is used to arbitrarily determine an imaging cross-section. The phase encoding gradient magnetic field Ge is used to change the phase of a magnetic resonance (MR) signal depending on a spatial position. The read-out gradient magnetic field Gr is used to change the frequency of the MR signal depending on a spatial position.

The gradient magnetic field power supply 103 supplies a current to the gradient coil 102. This configuration will be described below with reference to FIG. 2.

The couch 104 includes a couchtop 104a on which the subject P is placed. Under the control of the couch control circuitry 105, the couch 104 inserts the couchtop 104a into the hollow (imaging opening) of the gradient coil 102 in a state where the subject P is placed on the couchtop 104a.

In general, the couch 104 is installed such that the longitudinal direction thereof is parallel to the central axis of the static magnetic field magnet 101. The couch control circuitry 105 is configured to drive the couch 104 under the control of the calculator system 120. This allows the couchtop 104a to move in the longitudinal direction and up-and-down direction.

The transmission coil 106 is located on the inside of the gradient coil 102, is supplied with a radio frequency (RF) pulse from the transmitter circuitry 107, and generates a high-frequency magnetic field. The transmitter circuitry 107 supplies the transmission coil 106 with the RF pulse corresponding to the Larmor frequency determined based on the type of a target atomic nucleus and the strength of the magnetic field.

The reception coil 108 is located on the inside of the gradient coil 102, and receives the MR signal emitted from the subject P due to the effect of the high-frequency magnetic field. Upon receiving the MR signal, the reception coil 108 outputs the received MR signal to the receiver circuitry 109. For example, the reception coil 108 is a coil array including one or more, typically, a plurality of coil elements.

The receiver circuitry 109 generates MR data based on the MR signal output from the reception coil 108.

Specifically, the receiver circuitry 109 performs various types of signal processing, such as preamplification, intermediate frequency conversion, phase detection, low-frequency amplification, and filtering, on the MR signal output from the reception coil 108. Thus, the receiver circuitry 109 generates MR data as digitized complex number data. The MR data generated by the receiver circuitry 109 is also referred to as raw data.

The receiver circuitry 109 transmits the generated MR data to the sequence control circuitry 110. The receiver circuitry 109 may be provided in a gantry apparatus including the static magnetic field magnet 101 and the gradient coil 102.

In the present embodiment, the MR signal output from each coil element of the reception coil 108 is output to the receiver circuitry 109 in units called channels or the like by being distributed or combined as appropriate. Accordingly, in processing to be performed by the receiver circuitry 109 and the subsequent stage, the MR data is handled by each of the channels.

As for the relationship between the total number of coil elements and the total number of channels, the total numbers may be equal. Alternatively, the total number of channels may be smaller than the total number of coil elements, or conversely, the total number of channels may be larger than the total number of coil elements. The timing at which the MR signal is distributed or combined is not limited to that in the example described above. The MR signal or the MR data may be distributed or combined in units of channels at any timing prior to the processing to be performed by an image generation function 152 to be described below.

The sequence control circuitry 110 drives the gradient magnetic field power supply 103, the transmitter circuitry 107, and the receiver circuitry 109 to capture an image of the subject P based on information about an imaging sequence transmitted from the calculator system 120.

The term “imaging sequence” refers to a pulse sequence corresponding to each of a plurality of protocols included in an examination to be performed by the magnetic resonance imaging apparatus 100. The information about the imaging sequence defines the intensity of power to be supplied from the gradient magnetic field power supply 103 to the gradient coil 102, the timing at which the power is to be supplied, the intensity of the RF pulse to be transmitted from the transmitter circuitry 107 to the transmission coil 106, the timing at which the RF pulse is to be applied, the timing at which the MR signal is to be detected by the receiver circuitry 109, and the like.

The sequence control circuitry 110 drives the gradient magnetic field power supply 103, the transmitter circuitry 107, the receiver circuitry 109, the shim coil power supply, and the like to capture an image of the subject P. As a result, upon receiving MR data from the receiver circuitry 109, the sequence control circuitry 110 transfers the received MR data to the calculator system 120. The sequence control circuitry 110 is an example of a sequence control unit.

For example, the calculator system 120 controls the overall operation of the magnetic resonance imaging apparatus 100, collects data, and generates images. The calculator system 120 includes a processing circuitry 150, a storage circuitry 123, an input device 124, an output circuitry 125, and a display 126. The processing circuitry 150 includes an interface function 151, the image generation function 152, a control function 153, a calculation function 154, a measurement function 155, a detection function 156, and an informing function 157.

In the present embodiment, processing functions to be implemented by the interface function 151, the image generation function 152, the control function 153, the calculation function 154, the measurement function 155, and the detection function 156 are stored in the storage circuitry 123 in the form of a program that can be executed by a computer.

The processing circuitry 150 is a processor that reads out programs from the storage circuitry 123 and executes the programs to implement the functions corresponding to the programs. In other word, the processing circuitry 150 in the state where programs are read out includes the functions within the processing circuitry 150 illustrated in FIG. 1.

While FIG. 1 illustrates an example where, processing functions to be performed by the interface function 151, the image generation function 152, the control function 153, the calculation function 154, the measurement function 155, and the detection function 156 are implemented in a single processing circuitry 150, a plurality of independent processors may be combined to form the processing circuitry 150 and each processor may execute a program to implement each function.

In other words, the functions described above may be configured as programs and each processing circuitry may execute the programs, or a specific function may be implemented on a dedicated independent program executable circuitry.

The control function 153, the calculation function 154, the measurement function 155, and the detection function 156 included in the processing circuitry 150 are examples of an informing unit, a calculation unit, a measurement unit, and a detection unit, respectively.

The term “processor” described above refers to, for example, a circuitry such as a central processing unit (CPU), a graphical processing unit (GPU), an application specific integrated circuit (ASIC), or a programmable logic device (e.g., a simple programmable logic device (SPLD), a complex programmable logic device (CPLD), and a field-programmable gate array (FPGA)).

The processor reads out a program stored in the storage circuitry 123 and executes the program to thereby implement each function. Instead of storing programs in the storage circuitry 123, programs may be directly incorporated in the circuitry of the processor.

In this case, the processor reads out programs incorporated in the circuitry and executes the programs to thereby implement functions. The couch control circuitry 105, the transmitter circuitry 107, the receiver circuitry 109, the sequence control circuitry 110, and the like are also configured as electronic circuitry such as the above-described processor.

The processing circuitry 150 causes the interface function 151 to transmit information about an imaging sequence to the sequence control circuitry 110, and receives MR data from the sequence control circuitry 110. Upon receiving MR data through the interface function 151, the processing circuitry 150 stores the received MR data in the storage circuitry 123.

The processing circuitry 150 causes the image generation function 152 to generate an image using MR data received through the interface function 121 and data stored in the storage circuitry 123. The processing circuitry 150 transmits the image obtained by the image generation function 152 to the display 126 and the storage circuitry 123, as needed.

The processing circuitry 150 causes the control function 153 to control the overall operation of the magnetic resonance imaging apparatus 100. For example, the processing circuitry 150 causes the control function 153 to generate information about an imaging sequence based on imaging conditions input from an operator through the input device 124. The processing circuitry 150 causes the control function 153 to transmit the generated information about the imaging sequence to the sequence control circuitry 110, thereby controlling imaging processing.

The processing circuitry 150 causes the calculation function 154 to calculate the frequency dependency of the impedance in the gradient coil 102. The processing circuitry 150 causes the measurement function 155 to measure a voltage transition in self-discharge of a capacitor bank 21. The processing circuitry 150 causes the detection function 156 to detect an abnormality in at least one of the gradient coil 102 and the capacitor bank 21 using the calculated frequency dependency and the measured voltage transition.

The calculation function 154, the measurement function 155, and the detection function 156 are executed based on the gradient coils corresponding to the X-axis, the Y-axis, and the Z-axis, respectively. The calculation function 154, the measurement function 155, and the detection function 156 will be described in detail below.

The storage circuitry 123 stores MR data received by the processing circuitry 150 through the interface function 151, image data generated by the image generation function 152, and the like. For example, the storage circuitry 123 is a random access memory (RAM), a semiconductor memory element such as a flash memory, a hard disk, or an optical disk. The storage circuitry 123 corresponds to a storage unit.

The storage circuitry 123 stores programs corresponding to various functions to be executed by the processing circuitry 150. The storage circuitry 123 stores an equation relating to an energy conservation law for the gradient magnetic field power supply 103 and the gradient coil 102. This equation will be described below.

The storage circuitry 123 stores a plurality of reference values respectively corresponding to a plurality of frequencies of currents to be supplied to the gradient coil 102. The plurality of reference values corresponds to a threshold for detecting an abnormality (this threshold is hereinafter also referred to as an abnormality threshold) to be used in the detection function 156 to be described in detail below. The plurality of reference values corresponds to a reference curve representing frequency dependencies of the resistance values in the gradient coil 102. The reference curve is a curve representing the abnormality threshold to be used in the detection function 156.

The storage circuitry 123 stores a discharge characteristic indicating a transition of a voltage across the capacitor bank 21 (hereinafter also referred to as a voltage transition) due to self-discharge of the capacitor bank 21 at the time of installation of the magnetic resonance imaging apparatus 100.

The storage circuitry 123 stores imaging conditions relating to magnetic resonance imaging. The imaging conditions are dependent on a plurality of stored parameters. Examples of the imaging conditions include the number of captured images per unit time, a resolution, and a size of an effective field of view. The resolution is, for example, a resolution in a slice direction, a resolution in a read-out direction, or a resolution in a phase encoding direction.

The input device (input interface circuitry) 124 receives an input of various instructions and information from the operator. The input device 124 is, for example, a pointing device such as a mouse or a trackball, or an input device such as a keyboard.

The input device 124 is configured to input an instruction to start a function for comprehensively executing the calculation function 154, the measurement function 155, the detection function 156, and the like (this function is hereinafter also referred to as a degradation determination function). In the following description, assume that the operator that inputs an instruction to start the degradation determination function is a service person, but instead may be a healthcare worker (user) such as a radiological technologist that actually performs imaging processing on the magnetic resonance imaging apparatus 100.

The input device 124 is not limited only to an input device including physical operation members such as a mouse and a keyboard. Examples of the input interface circuitry include an electric signal processing circuitry configured to receive an electric signal corresponding to an input operation from an external input device provided separately from the magnetic resonance imaging apparatus 100 and output the received electric signal to various circuitries.

The output circuitry 125 causes the display 126 to display various information such as image data under the control of the control function 153 in the processing circuitry 150. The display 126 is, for example, a display device such as a liquid crystal display device.

The output circuitry 125 may output a predetermined warning to the display 126, a speaker (not illustrated), or the like. In this case, the predetermined warning is displayed on the display 126. The speaker outputs the predetermined warning as a sound under the control of the processing circuitry 150.

The predetermined warning is, for example, a warning indicating that performance degradation of the gradient coil 102 is detected. Thus, information about the predetermined warning is issued to the operator, the technologist, a maintenance provider, or the like. The output circuitry 125 corresponds to an output unit.

A measurement device 127x measures a voltage across a capacitor bank 21x that is provided between a power supply device 20 and an amplifier 22 in the gradient magnetic field power supply 103. The measurement device 127x is an example of the first detection unit. The measurement device 127x is, for example, a voltmeter provided for the capacitor bank 21x.

A measurement device 127y measures a voltage across a capacitor bank 21y that is provided between the power supply device 20 and the amplifier 22 in the gradient magnetic field power supply 103. The measurement device 127y is an example of the first detection unit. The measurement device 127y is, for example, a voltmeter provided for the capacitor bank 21y.

A measurement device 127z measures a voltage across a capacitor bank 21z that is provided between the power supply device 20 and the amplifier 22 in the gradient magnetic field power supply 103. The measurement device 127z is an example of the first detection unit. The measurement device 127z is, for example, a voltmeter provided for the capacitor bank 21z.

In the following description, the capacitor banks 21x, 21y, and 21z are collectively referred to as the capacitor bank 21 if there is no need to distinguish the capacitor banks 21x, 21y, and 21z from one another. The measurement devices 127x, 127y, and 127z are also collectively referred to as the measurement device 127 if there is no need to distinguish the measurement devices 127x, 127y, and 127z from one another.

Specifically, if a plurality of alternating currents with different frequencies is supplied to the gradient coil 102 at a predetermined time interval (hereinafter also referred to as a current supply period), the measurement device 127 measures the voltage (hereinafter also referred to as a drop voltage) across the capacitor bank 21 after the voltage drops during the current supply period. The measurement device 127 outputs the drop voltage for each frequency to the processing circuitry 150.

Further, the measurement device 127 measures a voltage transition of the capacitor bank 21 due to self-discharge of the capacitor bank 21 at the time of installation when the magnetic resonance imaging apparatus 100 is installed. The measurement device 127 outputs the voltage transition at the time of installation to the processing circuitry 150. The voltage transition at the time of installation is stored in the storage circuitry 123 as a discharge characteristic at the time of installation.

If an instruction to execute the degradation determination function is issued, the measurement device 127 measures the voltage transition of the capacitor bank 21 due to self-discharge of the capacitor bank 21 during execution of the degradation determination function. The measurement device 127 outputs the voltage transition during execution of the degradation determination function to the processing circuitry 150.

The measurement device 127 is not limited only to a voltmeter as long as the measurement device 127 can measure the drop voltage and the voltage transition.

As described above, the overall configuration of the magnetic resonance imaging apparatus 100 according to the embodiment will be described. Next, processing for the gradient magnetic field power supply 103 to supply a current to the gradient coil 102 will be described with reference to FIG. 2. FIG. 2 is a block diagram illustrating a configuration example of the gradient magnetic field power supply 103 and the like according to a first embodiment. The gradient magnetic field power supply 103 may include a current detection coil and an error amplifier, which are not illustrated in FIG. 2. Operations of the current detection coil and the error amplifier will be described below.

As illustrated in FIG. 2, for example, the gradient magnetic field power supply 103 includes the power supply device (post-regulator) 20, the capacitor bank 21 (X-axis gradient coil capacitor bank 21x, Y-axis gradient coil capacitor bank 21y, and Z-axis gradient coil capacitor bank 21z), and the amplifier 22 (power stage: X-axis gradient coil amplifier 22x, Y-axis gradient coil amplifier 22y, and Z-axis gradient coil amplifier 22z).

The power supply device 20 is a device having a power supply function for supplying energy to each of the amplifiers 22x to 22z to be described below. The power supply device 20 supplies each of the amplifiers 22x to 22z with energy required for the amplifiers 22x to 22z depending on the operations of the amplifiers 22x to 22z.

Specific examples of the power supply device 20 include a predetermined direct current (DC) power supply (alternating current (AC)/DC converter) that rectifies an alternating current output from an AC power supply. The AC/DC converter 20 converts an alternating current from an external power supply into a direct current.

The power supply device 20 is, for example, a DC power supply having constant voltage (CV)/constant current (CC) characteristics. In this case, if the load on the subsequent stage is large, the power supply device 20 functions as a constant current source, or conversely, if the load on the subsequent stage is small, the power supply device 20 functions as a constant voltage source. However, in a state described in the following embodiment, the load on the subsequent stage is large, so that the power supply device 20 functions as a constant current source.

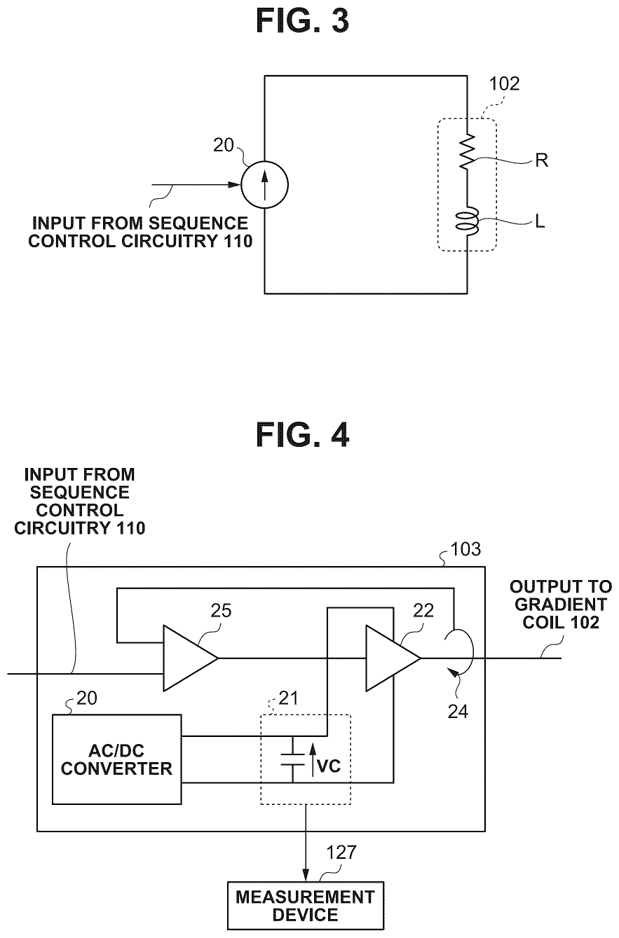

FIG. 3 illustrates a schematic circuitry example relating to the gradient coil 102. As illustrated in FIG. 3, the power supply device 20 corresponds to a constant current source. The constant current source 20 supplies a current to the gradient coil 102 based on an input from the sequence control circuitry 110. The gradient coil 102 includes, for example, a resistance R and a coil L.

The capacitor bank 21 supplies power (applies a voltage) to the amplifier 22 singly or together with the power supply device 20. In other words, the X-axis gradient coil capacitor bank 21x, the Y-axis gradient coil capacitor bank 21y, and the Z-axis gradient coil capacitor bank 21z are capacitors each having a battery function for supplying power to the amplifier 22 when the amount of power required to be supplied to the amplifier 22 is more than the amount of power that can be supplied from the power supply device 20.

The X-axis gradient coil capacitor bank 21x, the Y-axis gradient coil capacitor bank 21y, and the Z-axis gradient coil capacitor bank 21z indicate capacitor banks corresponding to the X-axis gradient coil 102x, the Y-axis gradient coil 102y, and the Z-axis gradient coil 102z, respectively.

Configuration examples of the capacitor banks 21x to 21z include electrolytic capacitors. The capacitor banks 21x to 21z are connected to the amplifiers 22x to 22z, respectively, and the power supply device 20, temporarily store power supplied from the power supply device 20, and discharge the stored power to the amplifiers 22x to 22z, respectively, as needed.

Examples of the functions of the capacitor bank are as follows. That is, if it is necessary to flow a large current to the gradient coils 102x to 102z of all the axes for a short period of time, the amount of required power may be more than the amount of power that can be temporarily supplied from the power supply device 20. Also, in such a case, the presence of the capacitor banks 21x to 21z makes it possible to stably supply power to the gradient coils 102x to 102z.

The amplifiers 22x to 22z are amplifiers 22 that convert a sequence waveform into a large current pulse. Each amplifier 22 operates based on power supplied from at least one of the power supply device 20 and the capacitor bank 21, amplifies an input signal based on information about a gradient magnetic field waveform, and outputs the amplified signal to the gradient coil 102.

Specifically, the X-axis gradient coil amplifier 22x, the Y-axis gradient coil amplifier 22y, and the Z-axis gradient coil amplifier 22z are the amplifiers 22 corresponding to the X-axis gradient coil 102x, the Y-axis gradient coil 102y, and the Z-axis gradient coil 102z, respectively.

Each of the amplifiers 22x to 22z receives a control signal corresponding to the sequence waveform from the sequence control circuitry 110, amplifies and converts the received control signal into a large current pulse, and outputs the amplified and converted signal to the gradient coil 102.

As described above, the gradient magnetic field power supply 103 supplies the gradient coil 102 with a current required to execute an imaging sequence. The functions of the gradient magnetic field power supply 103 will be described in more detail below.

FIG. 4 illustrates a circuitry configuration example in the gradient magnetic field power supply 103. The gradient magnetic field power supply 103 has a circuitry configuration as illustrated in FIG. 4 for each of the X-axis, the Y-axis, and the Z-axis. As illustrated in FIG. 4, the gradient magnetic field power supply 103 further includes a current detector 24 and an error amplifier 25.

The gradient magnetic field power supply 103 receives a waveform of an input signal (hereinafter also referred to as an input signal waveform) input from the sequence control circuitry 110. The gradient magnetic field power supply 103 outputs a current (hereinafter also referred to as an output current) having a waveform corresponding to the input signal waveform to the gradient coil 102. When a waveform of the output current (hereinafter also referred to as a current waveform) output from the gradient magnetic field power supply 103 is supplied to the gradient coil 102, the gradient coil 102 generates a gradient magnetic field having substantially the same shape as the current waveform in an imaging region within the gantry apparatus.

The current detector 24 detects the current waveform of the output current supplied from the amplifier 22 to the gradient coil 102. The current detector 24 outputs the detected current waveform to the error amplifier 25. While FIG. 4 illustrates the current detector 24 as a coil (current detection coil), the current detector 24 is not limited to a coil. A current detector having any other configuration may also be used as long as the current detector can detect the current waveform.

The error amplifier 25 receives the input signal waveform input from the sequence control circuitry 110. As illustrated in FIG. 4, the error amplifier 25 corresponds to, for example, an operational (OP) amplifier in a feedback control circuitry. The error amplifier 25 compares the input signal waveform with the current waveform.

In this case, the error amplifier 25 functions as a comparator (e.g., differential amplification circuitry). The error amplifier 25 outputs an error signal to the amplifier 22 based on a difference between the input signal waveform and the current waveform.

The amplifier 22 amplifies the error signal to a large current. In this case, the amplified large current has a current waveform that substantially matches the input signal waveform. Specifically, the amplifier 22 generates a current waveform corresponding to the gradient magnetic field waveform. The amplifier 22 outputs the amplified large current to the gradient coil 102.

A power supply voltage to be applied to the amplifier 22 is a DC voltage generated by the AC/DC converter 20. The current detector 24 and the error amplifier 25 are provided for each of the gradient coils respectively corresponding to the axes. Negative feedback of the output current is performed by the current detector 24, and thus feedback control using the input signal waveform and the current waveform of the output current is performed on the output current.

As illustrated in FIGS. 2 and 4, the capacitor bank 21 is provided between the AC/DC converter 20 and the amplifier 22. The capacitor bank 21 is connected in parallel to the output from the AC/DC converter 20.

The capacitor bank 21 and the AC/DC converter 20 supply power to the gradient coil 102. The gradient magnetic field power supply 103 can cause the capacitor bank 21 to temporarily supply a large current to the gradient coil 102. Such a control operation of temporarily supplying a large current from the gradient magnetic field power supply 103 is hereinafter also referred to as current control.

In a case where the impedance (e.g., resistance) of the gradient coil 102 is higher than a predetermined value due to, for example, an individual defect (or performance degradation) of the gradient coil 102, the gradient coil 102 additionally consumes energy. Thus, the gradient coil 102 having a higher impedance than the predetermined value may cause image quality degradation and damages to the gradient magnetic field power supply 103 and the gradient coil 102 itself.

In addition, even when the impedance further increases, the above-described current control functions in the gradient magnetic field power supply 103. Therefore, the gradient magnetic field power supply 103 attempts to output the current having the current waveform conforming to the input signal waveform to the gradient coil 102 by increasing the output voltage to the amplifier 22. As a result, if the impedance of the gradient coil 102 increases, energy to be applied to the gradient coil 102 also increases, which may cause further damages.

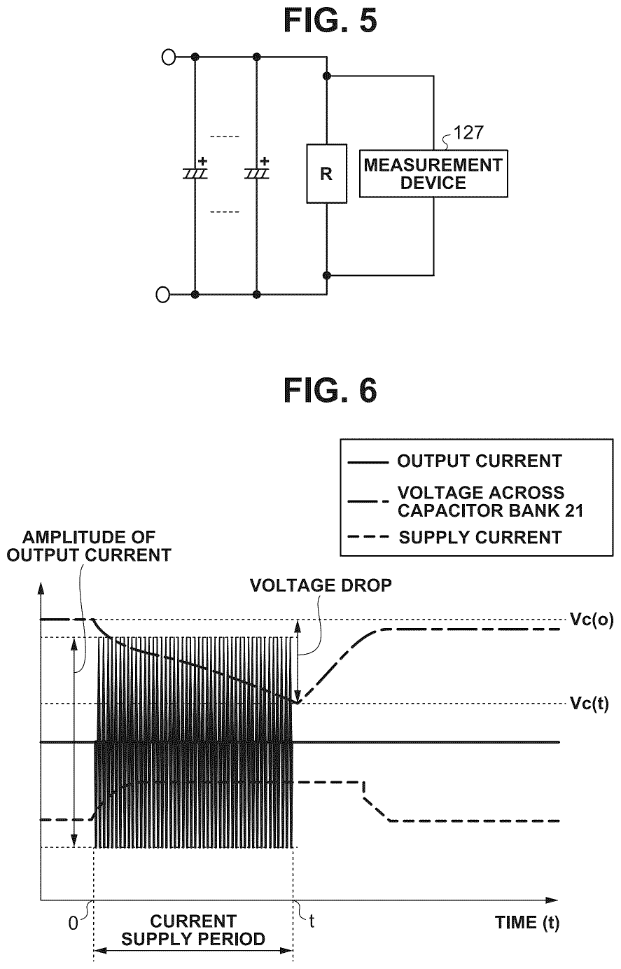

FIG. 5 illustrates an example of a connection relation between the capacitor bank 21 and the measurement device 127. As illustrated in FIG. 5, the capacitor bank 21 includes a plurality of capacitors connected in parallel and a discharge resistance R. The measurement device 127 is connected to both ends of the discharge resistance R.

Thus, the measurement device 127 can measure the drop voltage and the voltage transition of the capacitor bank 21.

A configuration relating to processing for estimating the impedance (resistance) of the gradient coil 102 so as to avoid the above-described damages and image quality degradation in the magnetic resonance imaging apparatus 100 according to the embodiment will be described below.

A background of the magnetic resonance imaging apparatus 100 according to the embodiment will now be described. An energy balance in a gradient magnetic field generation system including the gradient magnetic field power supply 103 and the gradient coil 102 is represented by the following Equation (1).

$${E}_{a} + {E}_{g} = {E}_{c} + {E}_{p} \qquad ( 1 )$$

In Equation (1), Eₐ represents energy to be consumed in each of the X-axis gradient coil amplifier 22x, the Y-axis gradient coil amplifier 22y, and the Z-axis gradient coil amplifier 22z.

E_{g} represents energy to be consumed in each of the X-axis gradient coil 102x, the Y-axis gradient coil 102y, and the Z-axis gradient coil 102z. E_{c} represents energy supplied from the X-axis gradient coil capacitor bank 21x, the Y-axis gradient coil capacitor bank 21y, and the Z-axis gradient coil capacitor bank 21z to the X-axis gradient coil 102x, the Y-axis gradient coil 102y, and the Z-axis gradient coil 102z, respectively.

Eₚ represents energy supplied from the power supply device 20 to each of the X-axis gradient coil 102x, the Y-axis gradient coil 102y, and the Z-axis gradient coil 102z.

Equation (1) is an equation relating to the energy conservation law in which energy to be supplied is equal to energy to be consumed in the gradient coil for each axis in the gradient magnetic field generation system. Equation (1) of the energy conservation law is established for, for example, each axis as illustrated in FIG. 2.

Eₐ illustrated in FIG. 2 represents energy to be consumed in the Y-axis gradient coil amplifier 22y. E_{g} illustrated in FIG. 2 represents energy to be consumed in the Y-axis gradient coil 102y. E_{c} illustrated in FIG. 2 represents energy supplied from the Y-axis gradient coil capacitor bank 21y to the Y-axis gradient coil 102y. Eₚ illustrated in FIG. 2 represents energy supplied from the power supply device 20 to the Y-axis gradient coil 102y.

That is, Equation (1) indicates that the sum of the energy consumption Eₐ in the amplifier 22 and the energy consumption E_{g} in the gradient coil 102 is equal to the sum of the supplied energy Eₚ from the AC/DC converter 20 and the supplied energy E_{c} from the capacitor bank 21. The voltage across the capacitor bank 21 can be derived from Equation (1) of the energy conservation law.

Specifically, E_{c} is represented by Equation (2).

$${E}_{c} = \frac{1}{2} {{CV}_{c} ( 0 )}^{2} - \frac{1}{2} {{CV}_{c} ( t )}^{2} \qquad ( 2 )$$

In Equation (2), C represents the capacitance of each of the X-axis gradient coil capacitor bank 21x, the Y-axis gradient coil capacitor bank 21y, and the Z-axis gradient coil capacitor bank 21z.

V_{c}(t) represents the voltage across each of the X-axis gradient coil capacitor bank 21x, the Y-axis gradient coil capacitor bank 21y, and the Z-axis gradient coil capacitor bank 21z at time t.

V_{c}(0) represents the voltage across each of the X-axis gradient coil capacitor bank 21x, the Y-axis gradient coil capacitor bank 21y, and the Z-axis gradient coil capacitor bank 21z when t=0, that is, in an initial state.

Specifically, Eₚ is represented by the following Equation (3).

$${E}_{p} = {\int }_{0}^{t} {V}_{c} ( {t}^{′} ) {I}_{p} ( {t}^{′} ) {dt}^{′} \qquad ( 3 )$$

In Equation (3), Iₚ(t′) represents a value of a current supplied from the power supply device 20 at time t′. In the following embodiment, a case where the power supply device 20 operates so that the value of the current to be supplied is set to a predetermined value. Iₚ is hereinafter also referred to as a supplied current.

Eₐ is represented by, for example, Equation (4).

$${E}_{a} = {\int }_{0}^{t} ( α {I ( {t}^{′} )}^{2} + β I ( {t}^{′} ) + γ ) {dt}^{′} \qquad ( 4 )$$

In Equation (4), I(t′) represents a value of a current output from each of the amplifiers 22x, 22y, and 22z at time t′. This also represents the value of the current supplied to each of the gradient coils 102x, 102y, and 102z. In addition, α, β, and γ represent predetermined parameters that are empirically calculated. I(t) is hereinafter also referred to as an output current.

In other words, although the X-axis gradient coil amplifier 22x, the Y-axis gradient coil amplifier 22y, and the Z-axis gradient coil amplifier 22z are actually formed of complicated circuitries, it can be considered that the total energy consumption is associated with a final output current I(t′).

These effects are represented by, for example, coefficients α, β, and γ. γ represents energy consumption (idling loss of the amplifier 22) in each of the X-axis gradient coil amplifier 22x, the Y-axis gradient coil amplifier 22y, and the Z-axis gradient coil amplifier 22z when the output current I(t′) is “0”.

β represents energy consumption (loss due to a diode, a transistor, and the like in the amplifier 22) in each of the X-axis gradient coil amplifier 22x, the Y-axis gradient coil amplifier 22y, and the Z-axis gradient coil amplifier 22z in a linear portion with respect to the output current I(t′).

α represents a coefficient (resistance loss in the amplifier 22) obtained by calculating energy consumption in each of the X-axis gradient coil amplifier 22x, the Y-axis gradient coil amplifier 22y, and the Z-axis gradient coil amplifier 22z in a non-linear portion with respect to the output current I(t′), assuming that the secondary non-linear effect is dominant over the output current I(t′).

The output current I(t′) corresponds to the waveform of the gradient magnetic field in the information about the imaging sequence. On the other hand, if the waveform of the gradient magnetic field is determined, the output current I(t′) is determined. Accordingly, if the imaging sequence is determined, the output current I(t′) is a known variable. In other words, the output current I(t′) is an alternating current to be supplied to the gradient coil 102.

It is considered that E_{g} can be written as a function system such as Equation (5).

$${E}_{a} = {\int }_{0}^{t} f ( R ( ω ) , I ( {t}^{′} ) ) {dt}^{′} \qquad ( 5 )$$

In Equation (5), R represents the resistance of the gradient coil 102, and ω represents the frequency of the alternating current (output current I) to be supplied to the gradient coil 102.

Specifically, energy to be consumed in each of the X-axis gradient coil 102x, the Y-axis gradient coil 102y, and the Z-axis gradient coil 102z is represented as a value obtained by integrating a function f between a resistance R(ω) and the output current I(t′) flowing to each of the gradient coils 102x, 102y, and 102z at time t′ by time during the current supply period from “0” to “t” when the current flows to the gradient coil.

Energy consumption at time t′ is dependent on the output current I(t′). The resistance R in an equivalent circuitry of each of the X-axis gradient coil 102x, the Y-axis gradient coil 102y, and the Z-axis gradient coil 102z is dependent on the frequency ω of the output current I(t′).

As a background of the magnetic resonance imaging apparatus 100 according to the present embodiment, the actual gradient coils 102x to 102z have complicated electric and magnetic characteristics.

Examples of such characteristics include the skin effect. The skin effect refers to the effect in which, when an alternating current flows through a conductor, the current density on a conductor surface increases and the current density decreases in a direction away from the conductor surface.

When a high-frequency current flows through the conductor, the current is blocked at a location away from the conductor surface due to an electromotive force caused by a mutual inductance in the conductor, so that the current density decreases. As a result, the current density tends to concentrate on a region with a low depth corresponding to a skin depth in the alternating current, so that the electric resistance increases. Typically, as the skin effect, the AC electric resistance increases in proportion to the square root of the frequency ω.

Examples of such characteristics include a heat loss due to an eddy current. The term “eddy current” used herein refers to an inductive current generated in the conductor due to a rapid change in the magnetic field. The eddy current generated in the conductor is converted into Joule heat in the conductor and causes the gradient coil 102 to generate heat.

In view of the above, the resistance R of the gradient coil 102 is not uniquely determined. Accordingly, the frequency characteristic of the resistance R of the gradient coil 102 is reproduced using an equivalent circuitry model of the gradient coil 102 as illustrated in FIG. 3. Specifically, the energy consumption E_{g} in the gradient coil 102 is represented by, for example, the following Equation (6).

$$\begin{matrix}{E}_{g} = {\int }_{0}^{t} \sqrt{{R ( ω )}^{2} + {( ω L ( ω ) )}^{2} {I ( {t}^{′} )}^{2} {dt}^{′}} \\ = \sqrt{{R ( ω )}^{2} + {( ω L ( ω ) )}^{2} {\int }_{0}^{t} {I ( {t}^{′} )}^{2} {dt}^{′}}\end{matrix} \qquad ( 6 )$$

The equation representing the relation between the voltage across the capacitor bank 21 and the impedance of the gradient coil 102 can be derived as the following Equation (7) using the above-described Equations (1) to (6).

$$\sqrt{{R ( ω )}^{2} + {( ω L ( ω ) )}^{2}} = \frac{\begin{matrix}\frac{1}{2} {{CV}_{c} ( 0 )}^{2} - \frac{1}{2} {{CV}_{c} ( t )}^{2} + \\ {\int }_{0}^{t} \{ {V}_{c} ( {t}^{′} ) {I}_{p} ( {t}^{′} ) - ( α I {( {t}^{′} )}^{2} + β I ( {t}^{′} ) + γ ) \} {dt}^{′}\end{matrix}}{{\int }_{0}^{t} {I ( {t}^{′} )}^{2} {dt}^{′}} \qquad ( 7 )$$

In Equation (7), C, α, β, and γ represent predetermined parameters as described above and are known amounts. The supplied current Iₚ(t) represents the known amount determined based on the specifications of the power supply device 20. The output current I(t) represents the known amount determined based on the alternating current supplied to the gradient coil 102. ω represents the frequency of the output current I(t) and indicates the known amount determined based on the alternating current supplied from the gradient coil 102.

The above-described Equation (7) is established so as to correspond to the gradient coil 102 for each of the X-axis, the Y-axis, and the Z-axis.

L(ω) represents the inductance in the gradient coil 102 and indicates the known amount dependent on the frequency ω of the output current I(t). L(ω) is preliminarily stored in the storage circuitry 123 as, for example, a correspondence table (hereinafter also referred to as an L(ω) correspondence table) for the inductance with respect to the frequency of the output current.

The L(ω) correspondence table is stored in the storage circuitry 123 in association with each of the X-axis, the Y-axis, and the Z-axis. An integration range “0” to “t in Equations (3) to (7) corresponds to the current supply period in which the output current is supplied to the gradient coil 102.

The resistance R(ω) of the gradient coil 102 is represented as the following Equation (8) by solving Equation (7) for R(ω).

$${R ( ω ) = \sqrt{\{ \frac{\begin{matrix}\frac{1}{2} {{CV}_{c} ( 0 )}^{2} - \frac{1}{2} {{CV}_{c} ( {t}^{′} )}^{2} + \\ {\int }_{0}^{t} \{ {V}_{c} ( {t}^{′} ) {I}_{p} ( {t}^{′} ) - ( α I {( {t}^{′} )}^{2} + β I ( {t}^{′} ) + γ ) \} {dt}^{′}\end{matrix}}{{\int }_{0}^{t} {I ( {t}^{′} )}^{2} {dt}^{′}}} \}}^{2} - {( ω L ( ω ) )}^{2} \qquad ( 8 )$$

R(ω) changes with time due to a temporal change, or a change over time (degradation over time) of the gradient coil 102. In Equation (8), R(ω) and V_{c}(t) are unknown variables. Accordingly, the measurement device 127 measures the voltage V_{c}(t) at time t across the capacitor bank 21 in the output current I(t) having the frequency ω. If an initial value (hereinafter also referred to as an initial voltage) of the voltage V_{c}(t) at t=0 is determined, the value of the resistance R(ω) can be calculated by Equation (8).

Specifically, the value of the resistance R(ω) of the gradient coil for each of the X-axis, the Y-axis, and the Z-axis can be calculated by measuring the voltage V_{c}(t) across the capacitor bank 21 of the gradient coil 102 for each of the X-axis, the Y-axis, and the Z-axis.

Assume that the initial voltage V_{c}(0) is stored in the storage circuitry 123. The initial voltage V_{c}(0) may be measured by the measurement device 127. Specifically, the processing circuitry 150 can cause the calculation function 154 to calculate (estimate) the resistance R(ω) of the gradient coil corresponding to the frequency ω using the measured drop voltage.

### (Calculation Function)

The calculation function 154 to be executed by the processing circuitry 150 will be described below.

For example, when an instruction to start the degradation determination function is issued by the operator through the input device 124, the processing circuitry 150 reads out a program (hereinafter also referred to as a calculation program) relating to the calculation function 154 and the L(ω) correspondence table from the storage circuitry 123.

The processing circuitry 150 loads the calculation program into the memory of the processing circuitry 150 itself and executes the loaded calculation program. In this case, the processing circuitry 150 functions as the determination unit. The determination unit determines a value corresponding to the impedance of the gradient coil 102 based on a voltage displacement of the capacitor bank 21 measured by the measurement device 127.

The calculation program can be executed at any timing, or on an arbitrary date and time set by the operator, a maintenance provider, or the like. The calculation program is a program relating to the following three operations and the like.

A first operation is an operation in which the sequence control circuitry 110 is controlled based on the calculation program, to thereby supply the output current I(t) corresponding to each of a plurality of frequencies ω to the gradient coil 102. The calculation program incorporates the plurality of frequencies ω and the current supply period. In the first operation, the output current I(t) is supplied to the gradient coil 102 during the current supply period at each of the plurality of frequencies.

The first operation may be executed on the gradient coil 102 of each axis, or may be executed on a plurality of gradient coils 102. Various functions, various processing, various operations, and the like relating to the gradient coil 102 of each axis can be understood as appropriate by replacing the terms used in the following description with terms corresponding to the respective axes.

A second operation is an operation in which the measurement device 127 is controlled based on the calculation program, to thereby measure the drop voltage V_{c}(t) across the capacitor bank 21 in the gradient magnetic field power supply 103 during the current supply period. In the current supply period, the measurement device 127 monitors the drop voltage V_{c}(t) of the capacitor bank 21, thereby identifying a minimum value of the drop voltage V_{c}(t).

A third operation is an operation in which the resistance of the gradient coil 102 is calculated using the output current I(t), the frequency ω of the output current I(t), the drop voltage V_{c}(t), the initial voltage V_{c}(0), the value of the inductance L(ω) corresponding to the frequency ω, and Equation (8). In the third operation, the processing circuitry 150 may calculate the impedance of the gradient coil 102 using Equation (7) instead of using Equation (8).

The processing circuitry 150 controls the gradient magnetic field power supply 103 through the sequence control circuitry 110 based on the calculation program. Specifically, the sequence control circuitry 110 supplies the alternating current (output current) I(t) having the frequency ω to the amplifier 22 during the current supply period. The output current I(t) is, for example, a sine wave having the frequency ω, and is expressed as, for example, I(t)=I₀×sin(ωt).

Assume herein that I₀ represents a value indicating the amplitude of the output current I(t) and the value is constant in the third operation.

In this case, the measurement device 127 measures the drop voltage V_{c}(t). The processing circuitry 150 reads out the value of the inductance L(ω) corresponding to the frequency ω from the storage circuitry 123. Further, the processing circuitry 150 reads out the value of the supplied current Iₚ output from the AC/DC converter 20 from the storage circuitry 123.

FIG. 6 is a graph illustrating an example of each of the voltage V_{c}, the supplied current Iₚ, and the output current I of the capacitor bank 21 during the current supply period. As illustrated in FIG. 6, in the current supply period, the voltage across the capacitor bank 21 drops from the initial voltage V_{c}(0) to the drop voltage V_{c}(t). The amplitude of the output current illustrated in FIG. 6 corresponds to I₀.

The processing circuitry 150 substitutes the drop voltage V_{c}(t), the initial voltage V_{c}(0), the output current I(t), the supplied current Iₚ(t), the frequency ω, and the inductance L(ω) into Equation (8), thereby calculating the value of the resistance R(ω) (hereinafter also referred to as a resistance value) of the gradient coil 102 corresponding to the frequency ω. By repeating the above-described processing on a plurality of frequencies, the processing circuitry 150 calculates a plurality of resistance values corresponding to the plurality of frequencies, respectively.

The processing circuitry 150 may calculate a curve representing the frequency dependency of the resistance R(ω) (this curve is hereinafter also referred to as a resistance-frequency curve) using the plurality of resistance values corresponding to the plurality of frequencies, respectively. In this case, the processing circuitry 150 monitors the voltage across the capacitor bank 21 for each output current output to the gradient coil 102, and generates the resistance-frequency curve.

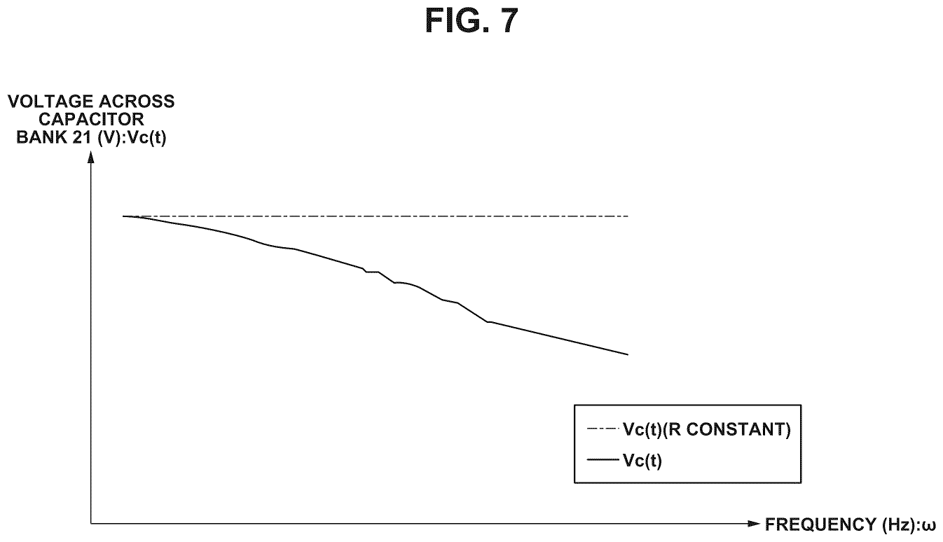

FIG. 7 is a graph illustrating an example of frequency dependencies of the voltage V_{c}(t) (R is constant) and the drop voltage V_{c}(t) of the capacitor bank 21 when the resistance of the gradient coil 102 is constant (frequency-independent). A broken line illustrated in FIG. 7 indicates the frequency dependency of the voltage V_{c}(t) (R is constant) across the capacitor bank 21 when the resistance of the gradient coil 102 is constant.

As illustrated in FIG. 7, when the resistance of the gradient coil 102 is not dependent on the frequency, the voltage V_{c}(t) (R is constant) across the capacitor bank 21 is not dependent on the frequency and takes a constant value.

A sold line illustrated in FIG. 7 indicates the frequency dependency of the drop voltage V_{c}(t) when the resistance of the gradient coil 102 is dependent on the frequency. As illustrated in FIG. 7, the drop voltage V_{c}(t) that is a voltage across the capacitor bank 21 is dependent on a change in the resistance of the gradient coil 102, and thus is dependent on the frequency ω of the output current I(t).

The frequency dependency of the voltage V_{c}(t) across the capacitor bank 21 depends on the fact that the drop voltage V_{c}(t) is less likely to be influenced by the inductor in the gradient coil 102. Accordingly, as illustrated in FIG. 7, a change in the resistance of the gradient coil 102 appears as a change in the voltage V_{c}(t) across the capacitor bank 21.

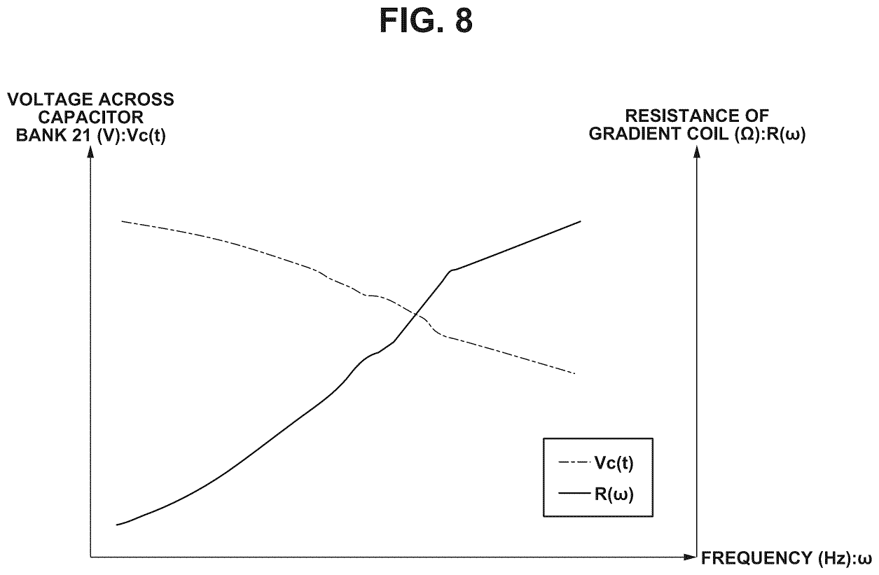

FIG. 8 is a graph illustrating a relationship between the drop voltage V_{c}(t) of the capacitor bank 21 with respect to the frequency ω of the output current I(t) and the resistance R(ω) of the gradient coil 102. A broken line illustrated in FIG. 8 indicates the frequency dependency of the drop voltage V_{c}(t) when the solid line illustrated in FIG. 7, or the resistance of the gradient coil 102 is dependent on the frequency.

A solid line illustrated in the graph of FIG. 8 indicates the frequency dependency of the resistance R(ω) of the gradient coil 102, that is, the resistance-frequency curve R(ω).

As illustrated in FIG. 8, as the value of the frequency ω increases, the drop voltage V_{c}(t) of the capacitor bank 21 decreases and the resistance R(ω) of the gradient coil 102 increases. Although the initial voltage V_{c}(0) is not illustrated in FIG. 8, the initial voltage V_{c}(0) is greater than the drop voltage V_{c}(t) for any of the frequencies. That is, V_{c}(0)>V_{c}(t) holds for any frequency ω.

As illustrated in FIG. 8, if the frequency of the output current I(t) is high, the calorific value in the gradient coil 102 increases, so that the resistance R(ω) increases. In this case, the voltage to be consumed in the capacitor bank 21 is increased so that a constant current is allowed to flow to the gradient coil 102. Accordingly, the drop voltage V_{c}(t) decreases along with an increase in the frequency.

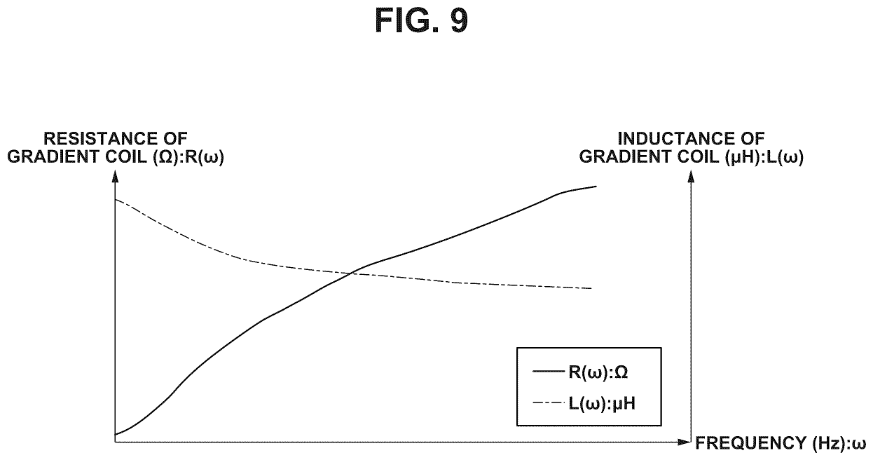

FIG. 9 is a graph illustrating frequency dependencies of the resistance-frequency curve R(ω) and the inductance L(ω) in the gradient coil 102. A broken line illustrated in the graph of FIG. 9 indicates a curve representing the frequency dependency of the inductance L(ω) in the gradient coil 102 (this curve is hereinafter also referred to as an inductance-frequency curve). A solid line illustrated in the graph of FIG. 9 indicates the resistance-frequency curve.

The resistance-frequency curve in the graph of FIG. 9 shifts upward, or the resistance value gradually increases, for example, with degradation of the gradient coil 102 over time. At a time when the magnetic resonance imaging apparatus 100 is installed in an examination room, the resistance-frequency curve is a positively sloped curve and includes small values on the entire curve.

The impedance calculated by the processing circuitry 150 is dependent on the frequency. In this case, a curve representing an impedance (hereinafter also referred to as an impedance-frequency curve) can be calculated as follows. For example, a value obtained by multiplying the inductance of the inductance-frequency curve in FIG. 9, the frequency, and 1/1,000,000, and a resistance value of the resistance-frequency curve in FIG. 9 are squared and added for each frequency, and the resultant value is subjected to square root extraction.

### (Measurement Function)

The measurement function 155 to be executed by the processing circuitry 150 will be described below. For example, during execution of the degradation determination function, when the frequency characteristic of the impedance of the gradient coil 102 is obtained and then a self-discharge measurement start instruction for the capacitor bank 21 is input according to an instruction from the operator through the input device 124, the processing circuitry 150 reads out a program relating to the measurement function 155 (hereinafter also referred to as a measurement program) from the storage circuitry 123.

The processing circuitry 150 loads the measurement program into the memory of the processing circuitry 150 itself and executes the loaded measurement program. In this case, the processing circuitry 150 functions as the measurement unit. The measurement unit measures a discharge period indicating a period during which the voltage across the capacitor bank 21 decreases from the first predetermined value (e.g., 400 V) to the second predetermined value (e.g., 200 V) based on the voltage transition of the capacitor bank 21 due to self-discharge that is measured by the measurement device 127.

The timing when the measurement program is executed is not limited to the example described above. The measurement program may be executed at any timing, or on an arbitrary date and time set by the operator, the maintenance provider, or the like.

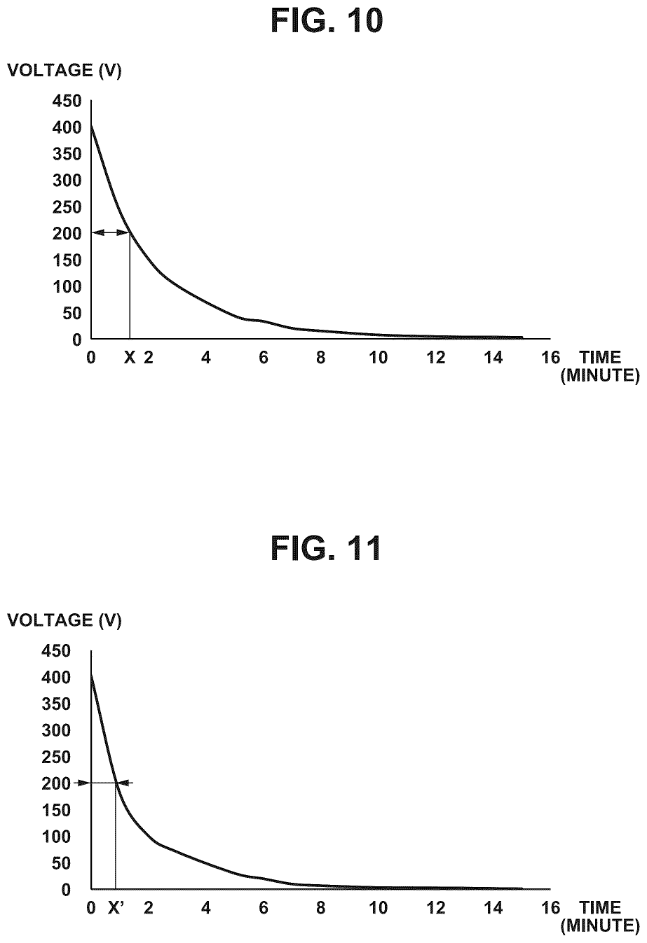

FIG. 10 is a graph illustrating an example of the discharge characteristic of the capacitor bank 21 at the time of installation. FIG. 10 illustrates results of the measurement of the voltage transition of the capacitor bank 21 by the measurement device 127 by self-discharge of the capacitor bank 21 at the time of installation of the magnetic resonance imaging apparatus 100.

In the example illustrated in FIG. 10, the processing circuitry 150 measures a period (X minutes) required for the voltage across the capacitor bank 21 to decrease from 400 V to 200 V as the discharge period. The discharge period at the time of installation is stored in the storage circuitry 123 together with the discharge characteristic of the capacitor bank 21 at the time of installation.

In this example, the period required for the voltage across the capacitor bank 21 to decrease from 400 V to 200 V is measured as the discharge period. However, the discharge period is not limited to the period measured in this example. For example, the processing circuitry 150 may measure the period during which the voltage across the capacitor bank 21 decreases from 200 V to 100 V as the discharge period.

FIG. 11 is a graph illustrating an example of the voltage transition of the capacitor bank 21 at the time of degradation. FIG. 11 illustrates results of the measurement of the voltage transition of the capacitor bank 21 by the measurement device 127 by causing the capacitor bank 21 to perform self-discharge when degradation in the capacitor bank 21 is found. In the example illustrated in FIG. 11, the processing circuitry 150 measures a period (X′ minutes) required for the voltage across the capacitor bank 21 to decrease from 400 V to 200 V as the discharge period.

As illustrated in FIGS. 10 and 11, the discharge period decreases as the capacitor bank 21 has degraded. This is because a leakage current is generated due to the degradation of the capacitor bank 21, for example, the degradation of an oxide film due to an applied voltage, so that electric charges of the capacitor go out rapidly.

### (Detection Function)

The detection function 156 to be executed by the processing circuitry 150 will be described below.

The processing circuitry 150 reads out a program relating to the detection function 156 (this program is hereinafter also referred to as a detection program) after the calculation function 154 is executed. In addition, the processing circuitry 150 reads out a plurality of reference values respectively corresponding to a plurality of frequencies for the output current from the storage circuitry 123. The reference values are reference values for the resistance of the gradient coil 102.

The processing circuitry 150 loads the detection program into the memory of the processing circuitry 150 itself and executes the loaded detection program. In this case, the processing circuitry 150 functions as the second detection unit. The second detection unit compares the frequency characteristic with the reference value, thereby detecting an abnormality in at least one of the gradient coil 102 and the capacitor bank 21.

For example, the processing circuitry 150 compares the calculated resistance values with the read reference values at each of the plurality of frequencies.

If the resistance value exceeds the reference value in at least one of the frequencies, the processing circuitry 150 detects an abnormality in at least one of the gradient coil 102 and the capacitor bank 21. On the other hand, if the resistance value is less than or equal to the reference value at all the frequencies, the processing circuitry 150 determines that the gradient coil 102 is normal.

If an abnormality is detected in at least one of the gradient coil 102 and the capacitor bank 21, the processing circuitry 150 outputs information indicating that an abnormality is detected in at least one of the gradient coil 102 and the capacitor bank 21 to the output circuitry 125.

In the example described above, the control function 153 in the processing circuitry 150 may be interlocked with the magnetic resonance imaging apparatus 100 so as to disable the magnetic resonance imaging apparatus 100.

The processing circuitry 150 may read out the reference curve representing the plurality of reference values corresponding to the plurality of frequencies, respectively, from the storage circuitry 123. In this case, the processing circuitry 150 compares the reference curve with the resistance-frequency curve. If the resistance-frequency curve exceeds the reference curve in at least one of the plurality of frequencies, the processing circuitry 150 detects an abnormality in at least one of the gradient coil 102 and the capacitor bank 21.

The processing circuitry 150 may compare the calculated impedances with the read reference values at each of the plurality of frequencies. In this case, the reference values are reference values for the impedance of the gradient coil 102.

The processing circuitry 150 may read out the reference curve representing the plurality of reference values corresponding to the plurality of frequencies, respectively, from the storage circuitry 123. In this case, the processing circuitry 150 compares the reference curve with the impedance-frequency curve. The comparison processing and subsequent processing are similar to those described above, and thus the description thereof is omitted.

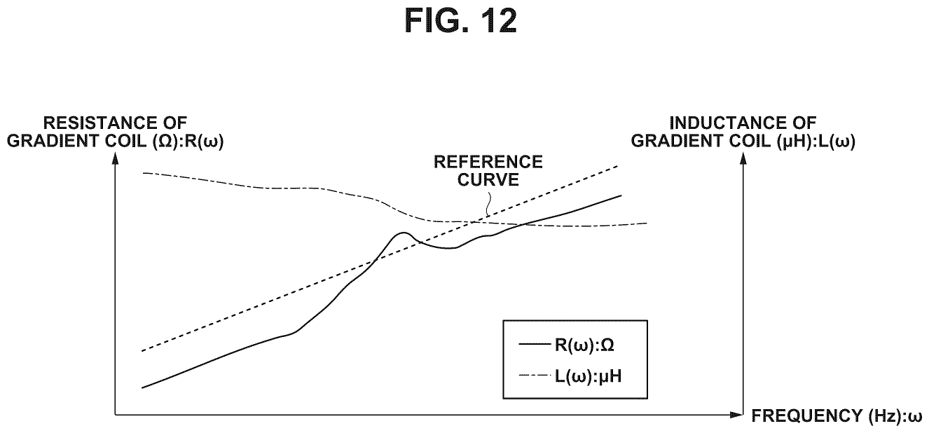

FIG. 12 illustrates an example of a graph relating to the detection of an abnormality in at least one of the gradient coil 102 and the capacitor bank 21 in the detection function 156.

A solid line illustrated in FIG. 12 indicates the resistance-frequency curve R(ω) representing the plurality of resistance values calculated by the calculation function 154 according to the frequency of the output current.

A dashed line illustrated in FIG. 12 indicates the reference curve read out from the storage circuitry 123. A broken line illustrated in FIG. 12 indicates the inductance-frequency curve L(ω) read out from the storage circuitry 123. As illustrated in FIG. 12, if the resistance-frequency curve R(ω) intersects with the reference curve, the processing circuitry 150 detects an abnormality in at least one of the gradient coil 102 and the capacitor bank 21.

After executing the measurement function 155, the processing circuitry 150 reads out the discharge characteristic of the capacitor bank 21 at the time of installation from the storage circuitry 123. In this case, the processing circuitry 150 compares the discharge period at the time of installation based on the discharge characteristic of the capacitor bank 21 at the time of installation with the discharge period measured during execution of the degradation determination function, thereby detecting an abnormality in the capacitor bank 21.

A configuration example of the processing circuitry 150 will now be described with reference to FIG. 10 illustrating the discharge characteristic of the capacitor bank 21 at the time of installation and FIG. 11 illustrating the voltage transition of the capacitor bank 21 during execution of the degradation determination function. In this example, the discharge period at the time of installation is X minutes, and the discharge period measured during execution of the degradation determination function is X′ minutes.

For example, if X′/X is less than a threshold (e.g., 0.5), the processing circuitry 150 detects an abnormality in at least the capacitor bank 21. On the other hand, if X′/X is more than or equal to the threshold, the processing circuitry 150 determines that the capacitor bank 21 is normal.

The processing circuitry 150 may store the threshold for the discharge period in the storage circuitry 123 and may detect an abnormality in at least the capacitor bank 21 based on the threshold for the discharge period. In this case, the threshold for the discharge period may be determined based on the discharge characteristic of the capacitor bank 21 at the time of installation.

For example, if the threshold determined based on the discharge characteristic of the capacitor bank 21 at the time of installation is X′ minutes, X′ minutes may be stored as the threshold for the discharge period. In this case, if the discharge period measured during execution of the degradation determination function is less than X′ minutes, the processing circuitry 150 may detect an abnormality in at least the capacitor bank 21.

### (Degradation Determination Function)

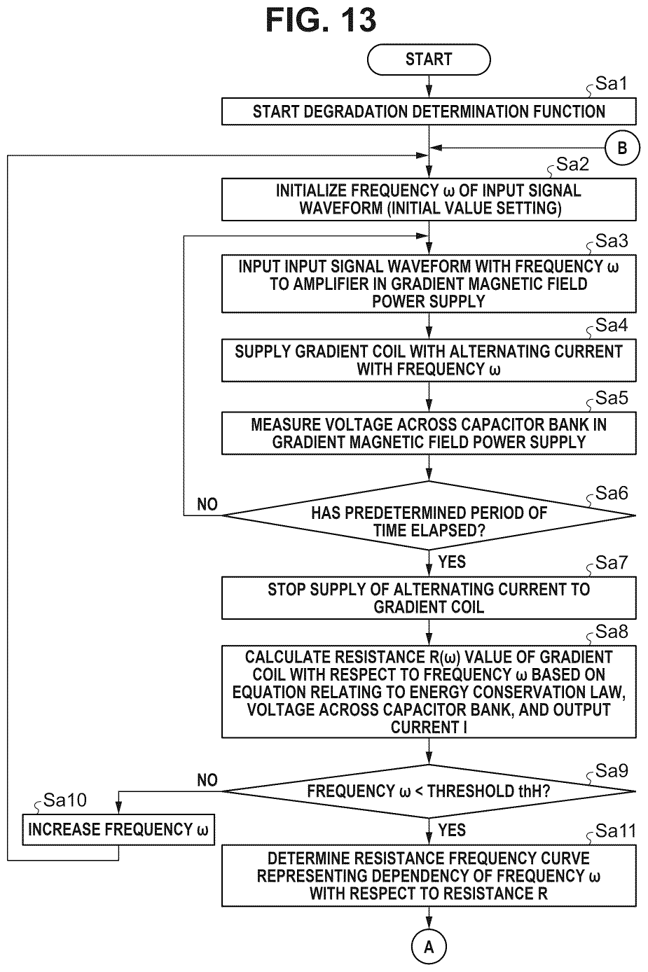

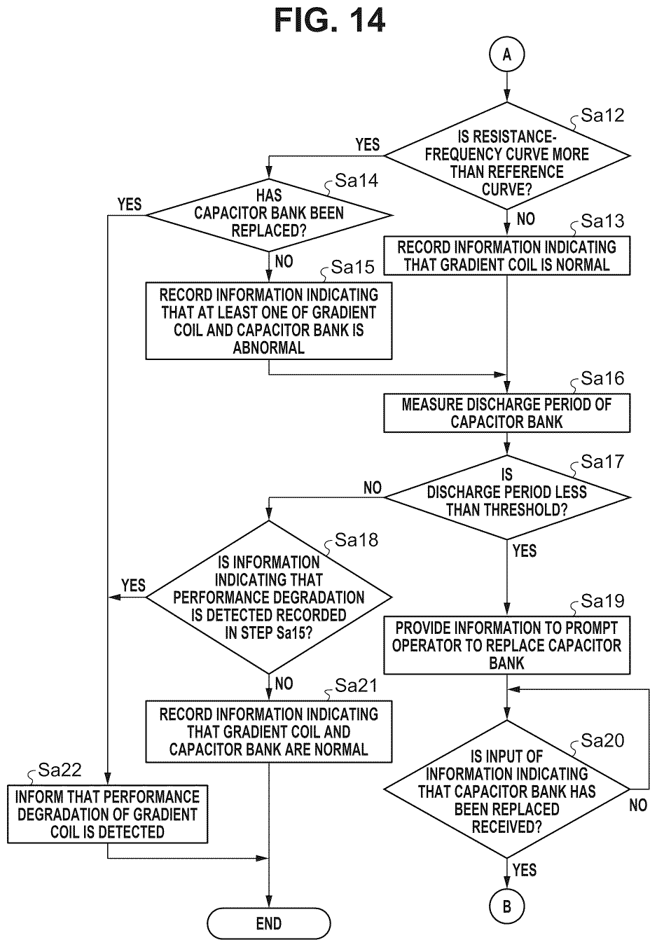

Processing relating to the degradation determination function (hereinafter also referred to as degradation determination processing) to be executed by the magnetic resonance imaging apparatus 100 according to the embodiment will be described. FIGS. 13 and 14 are flowcharts each illustrating an example of processing to be executed by the magnetic resonance imaging apparatus 100.

In step Sa1, the degradation determination function relating to the resistance of the gradient coil 102 is started in response to an instruction from the operator through the input device 124, or at a predetermined time. When the degradation determination function is started, the processing circuitry 150 reads out the calculation program from the storage circuitry 123 and executes the read calculation program.

Next, in step Sa2, the processing circuitry 150 initializes the frequency ω of the input signal waveform to be input to the gradient magnetic field power supply 103. The initialization of the frequency ω corresponds to, for example, setting of the frequency ω to an initial value.

The initial value of the frequency ω to be used for the degradation determination function is preliminarily stored in the storage circuitry 123. For ease of explanation, hereinafter assume that the initial value is, for example, a minimum natural number (hereinafter also referred to as a minimum value) in a preliminarily set plurality of frequencies (hereinafter also referred to as a frequency range). The frequency range is preliminarily stored in the storage circuitry 123. The frequency range corresponds to, for example, a frequency range represented by a horizontal axis in each of FIGS. 7 to 9 and FIG. 12.

In step Sa3, the input signal waveform having the frequency ω is input to the amplifier 22 in the gradient magnetic field power supply 103. The amplifier 22 generates the alternating current (output current I(t)) having the frequency ω based on voltages applied from the AC/DC converter 20 and the capacitor bank 21 and the input signal waveform. In step Sa4, the gradient magnetic field power supply 103 supplies the output current I(t) to the gradient coil 102.

The processing circuitry 150 starts measurement of a period triggered by the output current I(t) being supplied to the gradient coil 102. Specifically, the processing circuitry 150 measures the period during which the output current I(t) having the frequency ω is supplied to the gradient coil 102. In step Sa5, the measurement device 127 starts measurement of the voltage across the capacitor bank 21 triggered by the output current I(t) being supplied to the gradient coil 102.

The processing of steps Sa4 and Sa5 is repeated until the measured period has reached the current supply period, or a predetermined period has elapsed (NO in step Sa6). The measurement device 127 may execute measurement of the voltage across the capacitor bank 21 at a time when the current supply period has elapsed from time when the supply of the output current I(t) to the gradient coil 102 is started.

If the period measured by the processing circuitry 150 has reached the current supply period (YES in step Sa6), the processing proceeds to step Sa7. In step Sa7, the supply of the output current to the gradient coil 102 is stopped.

In step Sa8, the processing circuitry 150 calculates the value of the resistance R(ω) of the gradient coil 102 with respect to the frequency ω based on the equation relating to the energy conservation law for the gradient magnetic field power supply 103 and the gradient coil 102, the voltage across the capacitor bank 21, and the output current I(t). In other words, in the processing of step Sa8, the resistance value R(ω) with respect to the frequency ω of the output current I(t) is calculated.

If the frequency ω of the output current I(t) is less than a predetermined threshold thH (hereinafter also referred to as a maximum threshold) (NO in step Sa9), the processing proceeds to step Sa10. In step Sa10, the processing circuitry 150 increases the frequency ω.

The frequency ω may be increased by, for example, incrementing the frequency ω, adding a predetermined number to the frequency ω, or multiplying the frequency ω by a predetermined natural number. The maximum threshold thH is preliminarily stored in the storage circuitry 123. The maximum threshold thH corresponds to, for example, the maximum value in the frequency range. In this case, the processing of steps Sa3 to Sa9 is repeated.

The initial value is not limited to the minimum value, but instead may be any frequency value in the frequency range. In this case, in the processing of step Sa9, it is determined whether a plurality of output currents respectively corresponding to a plurality of preliminarily set frequencies is supplied to the gradient coil 102.

In the processing of step Sa10, if it is determined that the output currents having frequencies in the entire frequency range are not supplied to the gradient coil 102 (NO in step Sa9), the processing proceeds to step Sa10. In step Sa10, a frequency different from the frequency ω used in step Sa8 is set as a new frequency.

If it is determined that the plurality of output currents respectively corresponding to the plurality of frequencies in the entire frequency range is supplied to the gradient coil 102 (YES in step Sa9), the processing proceeds to step Sa11. In step Sa11, processing is executed as described below.

The initial value may be a maximum natural number (hereinafter also referred to as a maximum value) in the frequency range. In this case, in the processing of step Sa9, it is determined whether the frequency ω of the output current is higher than a threshold thL (hereinafter also referred to as a minimum threshold) corresponding to a minimum natural number in the frequency range. The minimum threshold thL is stored in the storage circuitry 123.

The minimum threshold thL corresponds to, for example, the minimum value in the frequency range. If it is determined that the frequency ω of the output current is higher than the minimum threshold thL (NO in step Sa9), the processing proceeds to step Sa10. In step Sa10, the frequency ω is decreased. The frequency ω may be decreased by, for example, decrementing the frequency ω with respect to the frequency ω, or subtracting a predetermined number from the frequency ω.

If it is determined that the frequency ω of the output current is lower than the minimum threshold thL (YES in step Sa9), the processing proceeds to step Sa11. In step Sa11, processing is executed as described below.

If it is determined that the frequency ω of the output current I(t) is more than or equal to the maximum threshold thH (YES in step Sa9), the processing proceeds to step Sa11. In step Sa11, the calculation function 154 in the processing circuitry 150 determines the resistance-frequency curve representing the dependency of the frequency ω with respect to the resistance R(ω) of the gradient coil 102.

The processing of step Sa8 may be executed immediately before the processing of step Sa11. The processing circuitry 150 reads out the reference curve from the storage circuitry 123. In step Sa12, the detection function 156 in the processing circuitry 150 compares the resistance-frequency curve with the reference curve.

If the resistance-frequency curve in the entire region of the plurality of frequencies is less than or equal to the reference curve (NO in step Sa12), the processing proceeds to step Sa13. In step Sa13, the detection function 156 in the processing circuitry 150 records information indicating that the gradient coil 102 is normal. For example, the processing circuitry 150 stores information indicating that the gradient coil 102 is normal in the storage circuitry 123. After that, the processing of the magnetic resonance imaging apparatus 100 proceeds to step Sa16 to be described below.

If the resistance-frequency curve exceeds the reference curve in at least one of the plurality of frequencies (YES in step Sa12), the processing proceeds to step Sa14. In step Sa14, the detection function 156 in the processing circuitry 150 determines whether the capacitor bank 21 has been replaced. For example, the processing circuitry 150 determines whether an input of information indicating that the capacitor bank 21 in which an abnormality is detected has been replaced is received from the operator.

If it is determined that the capacitor bank 21 has been replaced (YES in step Sa14), the processing proceeds to step Sa22. In step Sa22, the control function 153 in the processing circuitry 150 provides information indicating that performance degradation of the gradient coil 102 is detected, and then the processing ends. For example, the processing circuitry 150 controls the display 126 to display a message indicating that performance degradation of the gradient coil 102 is detected.

On the other hand, if it is determined that the capacitor bank 21 has not been replaced (NO in step Sa14), the processing proceeds to step Sa15. Then, in step Sa16, the measurement function 155 in the processing circuitry 150 measures the discharge period of the capacitor bank 21.

For example, the processing circuitry 150 reads out the measurement program from the storage circuitry 123. The processing circuitry 150 executes the measurement program, interrupts the flow of power from the power supply device 20 into the capacitor bank 21 and discharge of power from the capacitor bank 21 to the amplifiers 22x to 22z by switching, and causes the capacitor bank 21 to start self-discharge.

Further, the processing circuitry 150 causes the measurement device 127 to measure the voltage transition of the capacitor bank 21. Then, the processing circuitry 150 measures a period required for the voltage across the capacitor bank 21 to decrease from 400 V to 200 V as the discharge period.

After the measurement of the discharge period, the processing circuitry 150 reads out the discharge characteristic at the time of installation (including the discharge period at the time of installation) from the storage circuitry 123. The detection function 156 in the processing circuitry 150 compares the read discharge period at the time of installation with the discharge period measured in step Sa16. For example, in step Sa17, the processing circuitry 150 determines whether the measured discharge period/the discharge period at the time of installation is less than a threshold.

If the measured discharge period/the discharge period at the time of installation is more than or equal to the threshold (NO in step Sa17), the processing proceeds to step Sa18. In step Sa18, the processing circuitry 150 determines whether information indicating that performance degradation of the gradient coil 102 is detected is recorded in step Sa15.

If the information indicating that performance degradation of the gradient coil 102 is not recorded (NO in step Sa18), the processing proceeds to step Sa21. In step Sa21, the control function 153 in the processing circuitry 150 provides information indicating that the gradient coil 102 and the capacitor bank 21 are normal, and then the processing ends. For example, the processing circuitry 150 controls the display 126 to display a message indicating that no abnormality is detected in the gradient coil 102 and the capacitor bank 21.

If it is determined that the information indicating that performance degradation of the gradient coil 102 is detected is recorded (YES in step Sa18), the processing proceeds to step Sa22. In step Sa22, the control function 153 in the processing circuitry 150 provides information indicating that performance degradation of the gradient coil 102 is detected, and then the processing ends. For example, the processing circuitry 150 controls the display 126 to display a message indicating that performance degradation of the gradient coil 102 is detected.

If the measured discharge period/the discharge period at the time of installation is less than the threshold (YES in step Sa17), the processing proceeds to step Sa19. In step Sa19, the control function 153 in the processing circuitry 150 provides the operator with information to prompt the operator to replace the capacitor bank 21. For example, the processing circuitry 150 controls the display 126 to display a message to prompt the operator to replace the capacitor bank 21 when the measured discharge period/the discharge period at the time of installation is less than the threshold (abnormality is detected).

After step Sa19, in step Sa20, the control function 153 in the processing circuitry 150 determines whether an input of information indicating that the capacitor bank 21 in which an abnormality is detected has been replaced is received from the operator.

If it is determined that the input of information indicating that the capacitor bank 21 has been replaced is not received (NO in step Sa20), the processing of step Sa20 is repeated. If it is determined that the input of information indicating that the capacitor bank 21 has been replaced is received (YES in step Sa20), the processing returns to step Sa2.

The flowcharts illustrated in FIGS. 13 and 14 illustrate an example where the processing (step Sa16) of measuring the discharge period of the capacitor bank 21 is performed after the processing (steps Sa2 to Sa11) of calculating the impedance of the gradient coil 102 based on a voltage displacement of the capacitor bank 21. However, the processing of calculating the impedance of the gradient coil 102 may be performed after the processing of measuring the discharge period of the capacitor bank 21.

If self-discharge of the capacitor bank 21 is performed, a period for storing sufficient power in the capacitor bank 21 is required to perform the processing of calculating the impedance of the gradient coil 102 again. For this reason, the processing in the flowchart of FIG. 13 and the processing in the flowchart of FIG. 14 are carried out in this order, thereby enabling the magnetic resonance imaging apparatus 100 according to the present embodiment to efficiently execute the degradation determination function.

The flowcharts illustrated in FIGS. 13 and 14 illustrate a configuration example in which the processing of calculating the impedance of the gradient coil 102 and the processing of measuring the discharge period of the capacitor bank 21 are carried out at once. However, the processing of calculating the impedance of the gradient coil 102 and the processing of measuring the discharge period of the capacitor bank 21 may be performed at different opportunities, respectively.

The magnetic resonance imaging apparatus 100 according to the present embodiment described above obtains the frequency characteristic of the impedance of the gradient coil 102 based on the voltage displacement of the capacitor bank 21 measured by the measurement device 127, measures the discharge period of the capacitor bank 21 based on the voltage across the capacitor bank 21 measured by the measurement device 127, and detects an abnormality in at least one of the capacitor bank 21 and the gradient coil 102 based on the frequency characteristic of the impedance of the gradient coil 102 and the discharge period of the capacitor bank 21.

Thus, the magnetic resonance imaging apparatus 100 according to the present embodiment can estimate the resistance in the gradient coil 102 and a temporal change or a change over time of the impedance including the resistance by measuring the voltage across the capacitor bank 21. Consequently, the magnetic resonance imaging apparatus 100 according to the present embodiment can detect a change in the impedance including the resistance in the gradient coil 102 at an earlier stage. The magnetic resonance imaging apparatus 100 according to the present embodiment measures the discharge period of the capacitor bank 21, thereby making it possible to detect degradation of the capacitor bank 21. If an abnormality is detected in the calculated impedance, the magnetic resonance imaging apparatus 100 according to the present embodiment can determine whether degradation of the capacitor bank 21 is included in factors for the abnormality. In other words, the magnetic resonance imaging apparatus 100 according to the present embodiment can identify an abnormality section.

The above-described embodiment can be modified as appropriate by changing some of the configurations or functions included in the magnetic resonance imaging apparatus 100. Accordingly, modified examples of the embodiment described above will be described below as other embodiments. In the following description, differences from the above-described embodiment will be mainly described, and detailed descriptions of features common to the contents described above will be omitted. The modified examples to be described below may be individually carried out or may be combined as appropriate.

### MODIFIED EXAMPLE 1

The embodiment described above illustrates a configuration example in which the measurement devices 127x, 127y, and 127z are provided so as to correspond to the capacitor banks 21x, 21y, and 21z, respectively. In this modified example, a configuration in which the voltage across each of the capacitor banks 21x, 21y, and 21z is measured by a single measurement device 127 will be described.

In this modified example, in the case of measuring a voltage transition in self-discharge of the capacitor bank 21, the measurement function 155 in the processing circuitry 150 first interrupts the flow of power from the power supply device 20 into the capacitor bank 21x and discharge of power from the capacitor bank 21x to the amplifier 22x by switching, and causes the capacitor bank 21x to start self-discharge.

This configuration enables the measurement device 127 to measure the voltage transition in self-discharge of the capacitor bank 21x.

Next, the measurement function 155 in the processing circuitry 150 interrupts the flow of power from the power supply device 20 into the capacitor bank 21y and discharge of power from the capacitor bank 21y to the amplifier 22y by switching, and causes the capacitor bank 21y to start self-discharge.

This configuration enables the measurement device 127 to measure the voltage transition in self-discharge of the capacitor bank 21y.

Next, the measurement function 155 in the processing circuitry 150 interrupts the flow of power from the power supply device 20 into the capacitor bank 21z and discharge of power from the capacitor bank 21z to the amplifier 22z by switching, and causes the capacitor bank 21z to start self-discharge.

This configuration enables the measurement device 127 to measure the voltage transition in self-discharge of the capacitor bank 21z.

In this modified example, a dedicated imaging sequence for performing the processing of calculating the impedance of the gradient coil 102 is preliminarily set.

Specifically, an imaging sequence for calculating the impedance of the gradient coil 102x is preliminarily set based on the voltage displacement of the capacitor bank 21x, an imaging sequence for calculating the impedance of the gradient coil 102y is preliminarily set based on the voltage displacement of the capacitor bank 21y, and an imaging sequence for calculating the impedance of the gradient coil 102z is preliminarily set based on the voltage displacement of the capacitor bank 21z.

For example, in the imaging sequence for calculating the impedance of the gradient coil 102x based on the voltage displacement of the capacitor bank 21x, the gradient magnetic field power supply 103 supplies power only to the gradient coil 102x, and supplies no power to each of the gradient coils 102y and 102z.

With this configuration, even when the imaging sequence for calculating the impedance of the gradient coil 102x is executed based on the voltage displacement of the capacitor bank 21x, no voltage displacement occurs in each of the capacitor banks 21y and 21z. Accordingly, by measuring the voltage by the measurement device 127 measures, it becomes possible to obtain the voltage displacement of the capacitor bank 21x.

Similarly, the imaging sequence for calculating the impedance of the gradient coil 102y is executed based on the voltage displacement of the capacitor bank 21y, thereby making it possible to obtain the voltage displacement of the capacitor bank 21y, and the imaging sequence for calculating the impedance of the gradient coil 102z is executed based on the voltage displacement of the capacitor bank 21z, thereby making it possible to obtain the voltage displacement of the capacitor bank 21z.

The impedance of the gradient coil 102x, the impedance of the gradient coil 102y, and the impedance of the gradient coil 102z may be calculated using imaging sequences to be used in actual imaging processing.

In this case, in the case of calculating the impedance of the gradient coil 102x, the gradient magnetic field power supply 103 executes the imaging sequence to supply high power to the gradient coil 102x and to supply no power or low power to each of the gradient coils 102y and 102z.

In the case of calculating the impedance of the gradient coil 102y, the gradient magnetic field power supply 103 executes the imaging sequence to supply high power to the gradient coil 102y and to supply no power or low power to each of the gradient coils 102x and 102z.

In the case of calculating the impedance of the gradient coil 102z, the gradient magnetic field power supply 103 executes the imaging sequence to supply high power to the gradient coil 102z and to supply no power or low power to each of the gradient coils 102x and 102y.

According to this modified example, the voltage across each of the capacitor bank 21x, the capacitor bank 21y, and the capacitor bank 21z can be measured by a single measurement device 127, which leads to a reduction in the cost of the magnetic resonance imaging apparatus 100.

### MODIFIED EXAMPLE 2

The above-described embodiment illustrates a configuration example in which the voltage transition in self-discharge of the capacitor bank 21 is measured and compared with the voltage transition (discharge characteristic) in self-discharge of the capacitor bank 21 at the time of installation, thereby detecting an abnormality in the capacitor bank 21. In this modified example, a configuration in which the voltage transition in self-discharge of the capacitor bank 21 is stored over time and time for replacement of the capacitor bank 21 is predicted will be described.

In this modified example, the storage circuitry 123 stores a measurement result as the discharge characteristic of the capacitor bank 21 every time a voltage transition of the capacitor bank 21 due to self-discharge of the capacitor bank 21 is measured. Thus, the discharge characteristic of the capacitor bank 21 is stored in the storage circuitry 123 every time the voltage transition of the capacitor bank 21 due to self-discharge of the capacitor bank 21 is executed, thereby making it possible to record a temporal change of the discharge characteristic of the capacitor bank 21.

In this modified example, the processing circuitry 150 includes a function (an example of a prediction unit) for predicting time for replacement of the capacitor bank 21. The processing circuitry 150 according to this modified example refers to a temporal change of the discharge characteristic of the capacitor bank 21 every time the voltage transition of the capacitor bank 21 due to self-discharge of the capacitor bank 21 is executed, and predicts whether the measured discharge period/the discharge period at the time of installation is less than a threshold based on the temporal change.

The control function 153 in the processing circuitry 150 according to this modified example informs the operator of the time when the measured discharge period/the discharge period at the time of installation is predicted to be less than the threshold as time for replacement of the capacitor bank 21.

For example, the control function 153 in the processing circuitry 150 controls the display 126 to display a message indicating that it is necessary to replace the capacitor bank 21 in MM month YY year (at time when it is predicted that the measured discharge period/the discharge period at the time of installation will be less than the threshold).

According to this modified example, it is possible to inform the operator of the time it is predicted that the capacitor bank 21 needs to be replaced before an abnormality is actually detected in the capacitor bank 21. This configuration facilitates the operator to deal with the replacement of the capacitor bank 21 and the like if an abnormality is actually detected in the capacitor bank 21.

The instruction indicated in the processing procedure in the embodiment described above can be executed based on a program, which is software. A general-purpose calculator system may store this program in advance and may load this program to obtain the same advantageous effects as those of the magnetic resonance imaging apparatus 100 according to the embodiment described above.

The instruction described in the above-described embodiment is recorded as a program that can be executed by a computer on a magnetic disk (flexible disk, hard disk, etc.), an optical disk (compact disc (CD)-read-only memory (ROM), CD-recordable (R), CD-rewritable (RW), digital versatile disc (DVD)-ROM, DVD+R, DVD+RW, etc.), a semiconductor memory, or a recording medium similar to such recording media. A storage medium having any storage format may be used as long as the storage medium can be read by a computer or a built-in system.

In this case, the computer loads a program from such a storage medium, and causes a CPU to execute an instruction described in a program based on the program, thereby making it possible to implement an operation similar to the magnetic resonance imaging apparatus 100 according to the embodiment described above. In a case where a program is obtained or loaded by a computer, the program may be obtained or loaded via a network.

In addition, an operating system (OS), database management software, middleware (MW), such as a network, or the like running on the computer based on an instruction from a program installed on the computer or built-in system from a storage medium may execute some of the processing operations for implementing the above-described embodiments.

The storage medium is not limited only to a medium independent of the computer or built-in system, but also includes a storage medium that stores or temporarily stores a program by downloading the program transmitted via a local area network (LAN), the Internet, or the like.

The storage medium is not limited to a single storage medium. Examples of the storage medium according to the embodiment also include a case where processing according to the embodiment described above is executed using a plurality of media, and the media may have any configuration.

The computer or built-in system according to the embodiment is configured to execute each processing operation according to the above-described embodiments based on programs stored in a storage medium, and may have a configuration of any one of an apparatus composed of a personal computer, a microcomputer, and the like, a system including a plurality of apparatuses connected via a network, and the like.

The computer according to the embodiment is not limited only to a personal computer. Examples of the computer according to the embodiment also include an arithmetic processing unit, a microcomputer, or the like included in an information processing device. The computer is a generic term for devices and apparatuses configured to implement functions according to the embodiments based on programs.

According to at least one embodiment, at least one modified example, and the like described above, it is possible to identify an abnormality section.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic resonance imaging apparatus comprising:
a gradient coil configured to generate a gradient magnetic field;
a gradient magnetic field power supply including a power supply device configured to supply power, a capacitor configured to accumulate power supplied from the power supply device, and an amplifier configured to amplify an input signal and operate based on power supplied from at least one of the power supply device and the capacitor, the gradient magnetic field power supply being configured to output the amplified signal to the gradient coil; and
processing circuitry configured to:
detect a voltage across the capacitor;
determine a value corresponding to an impedance of the gradient coil;
measure a period required for the voltage across the capacitor to decrease from a first predetermined value to a second predetermined value by self-discharge based on the detected voltage; and
detect an abnormality in at least one of the capacitor and the gradient coil based on the determined value corresponding to the impedance and the measured period.

2. The magnetic resonance imaging apparatus according to claim 1, wherein the processing circuitry is further configured to, in a case where the determined value corresponding to the impedance is greater than a predetermined value and the measured period is less than a predetermined period, determine that an abnormality is detected in the capacitor.

3. The magnetic resonance imaging apparatus according to claim 1, wherein the processing circuitry is further configured to, in a case where the determined value corresponding to the impedance is greater than a predetermined value and the measured period is more than or equal to a predetermined period, determine that an abnormality is detected in the gradient coil.

4. The magnetic resonance imaging apparatus according to claim 1, wherein the processing circuitry is further configured to, in a case where the determined value corresponding to the impedance is less than or equal to a predetermined value and the measured period is less than a predetermined period, determine that an abnormality is detected in the capacitor.

5. The magnetic resonance imaging apparatus according to claim 1, wherein the processing circuitry is further configured to provide information to prompt to replace the capacitor in a case where an abnormality is detected in the capacitor.

6. The magnetic resonance imaging apparatus according to claim 5, wherein the processing circuitry is further configured to predict time when the period will be less than a predetermined period based on a temporal change of the period,
wherein the information about the predicted time is provided as time for replacement of the capacitor.

7. The magnetic resonance imaging apparatus according to claim 1, wherein the processing circuitry is further configured to provide information about an abnormality in the gradient coil in a case where an abnormality is detected in the gradient coil.

8. The magnetic resonance imaging apparatus according to claim 1, wherein the processing circuitry is further configured to determine a frequency characteristic of an impedance of the gradient coil to be the value corresponding to the impedance based on the detected voltage.

9. The magnetic resonance imaging apparatus according to claim 8, wherein processing of measuring the period is executed after processing of determining the frequency characteristic is executed.

10. A gradient magnetic power supply apparatus comprising:
a power supply device configured to supply power;
a capacitor configured to accumulate power supplied from the power supply device;
an amplifier configured to operate based on power supplied from at least one of the power supply device and the capacitor, amplify an input signal, and output the amplified signal to a gradient coil configured to generate a gradient magnetic field; and
processing circuitry configured to:
detect a voltage across the capacitor;
determine a value corresponding to an impedance of the gradient coil;
measure a period required for the voltage across the capacitor to decrease from a first predetermined value to a second predetermined value by self-discharge based on the detected voltage; and
detect an abnormality in at least one of the capacitor and the gradient coil based on the determined value corresponding to the impedance and the measured period.

11. An abnormality detection method to be performed by a gradient magnetic power supply apparatus comprising:
a power supply device configured to supply power;
a capacitor configured to accumulate power supplied from the power supply device;
an amplifier configured to operate based on power supplied from at least one of the power supply device and the capacitor, amplify an input signal, and output the amplified signal to a gradient coil configured to generate a gradient magnetic field; and
processing circuitry configured to detect a voltage across the capacitor, the abnormality detection method comprising:
determining a value corresponding to an impedance of the gradient coil;
measuring a period required for the voltage across the capacitor to decrease from a first predetermined value to a second predetermined value by self-discharge based on the detected voltage; and
detecting an abnormality in at least one of the capacitor and the gradient coil based on the determined value corresponding to the impedance and the measured period.

12. The abnormality detection method according to claim 11, wherein, in a case where the determined value corresponding to the impedance is greater than a predetermined value and the measured period is less than a predetermined period, it is determined that an abnormality is detected in the capacitor.

13. The abnormality detection method according to claim 11, wherein, in a case where the determined value corresponding to the impedance is greater than a predetermined value and the measured period is more than or equal to a predetermined period, it is determined that an abnormality is detected in the gradient coil.

14. The abnormality detection method according to claim 11, wherein, in a case where the determined value corresponding to the impedance is less than or equal to a predetermined value and the measured period is less than a predetermined period, it is determined that an abnormality is detected in the capacitor.

15. The abnormality detection method according to claim 11, wherein, in a case where an abnormality is detected in the capacitor, information to prompt to replace the capacitor is provided.

16. The abnormality detection method according to claim 15,
wherein time when the period will be less than the predetermined period is predicted based on a temporal change of the period, and
wherein information about the predicted time is provided as time for replacement of the capacitor.

17. The abnormality detection method according to claim 11, wherein, in a case where an abnormality is detected in the gradient coil, information about the abnormality in the gradient coil is provided.

18. The abnormality detection method according to claim 11, wherein a frequency characteristic of the impedance of the gradient coil is determined to be the value corresponding to the impedance based on the detected voltage.

19. The abnormality detection method according to claim 18, wherein processing of measuring the period is executed after processing of determining the frequency characteristic is executed.
